(19) United States
(12) Patent Application Publication
(10) Pub. No.: US 2026/0354253 A1
(43) Pub. Date: Nov. 5, 2026

(54) SEMICONDUCTOR PACKAGE AND PACKAGE-ON-PACKAGE INCLUDING THE SAME

(71) Applicant: Samsung Electronics Co., Ltd., Suwon-si (KR)

(72) Inventors: JIYOUNG PARK, Suwon-si (KR); UN-BYOUNG KANG, Suwon-si (KR); JUNGHOON KANG, Suwon-si (KR); Youngjoon Yun, Suwon-si (KR); BYOUNG WOOK JANG, Suwon-si (KR)

(21) Appl. No.: 19/342,903

(22) Filed: Sep. 29, 2025

(30) Foreign Application Priority Data
May 2, 2025 (KR) 10-2025-0058222

(51) Int. Cl. H10W 74/10; H10W 70/60; H10W 70/652; H10W 74/15; H10W 90/00

(52) U.S. Cl. CPC H10W 74/121; H10W 90/00; H10W 70/60; H10W 70/611; H10W 70/6528; H10W 74/15; H10W 90/401; H10W 90/724; H10W 90/734

(57) ABSTRACT

An embodiment of the present disclosure provides a semiconductor package including a first interconnection layer, a sub-package disposed on the first interconnection layer and comprising a second interconnection layer, an apertured interconnection layer disposed on the second interconnection layer and having a through hole, a first semiconductor chip disposed within the through hole, a first encapsulant filling a portion of the through hole and covering a portion of the first semiconductor chip, and a third interconnection layer disposed on the first encapsulant, a second encapsulant covering a portion of the sub-package, a second semiconductor chip disposed on the second encapsulant, a third encapsulant covering a portion of the second semiconductor chip, a fourth interconnection layer disposed on the third encapsulant, and a conductive post embedded in the third encapsulant and electrically connecting the sub-package and the fourth interconnection layer.

### CROSS-REFERENCE TO RELATED APPLICATION

This application claims priority to and the benefit of Korean Patent Application No. 10-2025-0058222 filed at the Korean Intellectual Property Office on May 2, 2025, the entire contents of which are incorporated herein by reference.

### BACKGROUND OF THE INVENTION

### (a) Field of the Invention

The present disclosure relates to a semiconductor package and a package-on-package including the same.

### (b) Description of the Related Art

In the semiconductor industry, a package-on-package structure is known in which an upper semiconductor package is stacked on a lower semiconductor package. The lower semiconductor package of the package-on-package may be manufactured, for example, by arranging a semiconductor chip on a front-side redistribution layer (FRDL), molding it with an encapsulant, and then forming a back-side redistribution layer (BRDL) electrically connected to the front-side redistribution layer on the encapsulant.

### SUMMARY OF THE INVENTION

Embodiments of the present disclosure provide a semiconductor package capable of improving product yield and productivity and a package-on-package device including the same. Embodiments of the present disclosure provide a semiconductor package and a package-on-package device assembly incorporating the package, which are configured to improve manufacturing yield.

Embodiments of the present disclosure provide a semiconductor package capable of preventing or reducing defects in a conductive post and a package-on-package device including the same. Embodiments of the present disclosure provide a semiconductor package and a package-on-package device assembly incorporating the package, which are configured to reduce the occurrence of defects in conductive posts.

An embodiment of the present disclosure provides a semiconductor package, including a first interconnection layer, a sub-package, disposed on the first interconnection layer and comprising a second interconnection layer, an apertured interconnection layer disposed on the second interconnection layer and having a through hole, a first semiconductor chip disposed within the through hole, a first encapsulant filling a portion of the through hole and covering a portion of the first semiconductor chip, and a third interconnection layer disposed on the first encapsulant, a second encapsulant covering a portion of the sub-package, a second semiconductor chip disposed on the second encapsulant, a third encapsulant covering a portion of the second semiconductor chip, a fourth interconnection layer disposed on the third encapsulant, and a conductive post embedded in the third encapsulant and electrically connecting the sub-package and the fourth interconnection layer.

Another embodiment of the present disclosure provides a semiconductor package, including a first interconnection layer, a sub-package, disposed on the first interconnection layer and electrically connected to the first interconnection layer and comprising a second interconnection layer; an intermediate interconnection pattern disposed on the second interconnection layer and electrically connected to the second interconnection layer and having a through hole; a first logic chip disposed within the through hole and electrically connected to the second interconnection layer; a first encapsulant filling a portion of the through hole and covering a portion of the first logic chip; and a third interconnection layer disposed on the first encapsulant and electrically connected to the intermediate interconnection pattern, a second encapsulant covering a portion of the sub-package, a second logic chip disposed on the second encapsulant and electrically connected to the third interconnection layer, a third encapsulant covering a portion of the second logic chip, a fourth interconnection layer disposed on the third encapsulant, and a conductive post embedded in the third encapsulant and electrically connecting the third interconnection layer and the fourth interconnection layer.

Another embodiment of the present disclosure provides a package-on-package, including a first semiconductor package, and a second semiconductor package disposed on the first semiconductor package, wherein the first semiconductor package includes a first interconnection layer, a sub-package a sub-package disposed on the first interconnection layer, a second encapsulant covering a portion of the sub-package, a second semiconductor chip disposed on the second encapsulant, a third encapsulant covering a portion of the second semiconductor chip, a fourth interconnection layer disposed on the third encapsulant, and a conductive post embedded in the third encapsulant and electrically connecting the sub-package and the fourth interconnection layer. The sub-package comprises a second interconnection layer, an intermediate interconnection pattern disposed on the second interconnection layer and having a through hole, a first semiconductor chip disposed within the through hole, a first encapsulant filling a portion of the through hole and covering a portion of the first semiconductor chip, and a third interconnection layer disposed on the first encapsulant.

Another embodiment of the present disclosure provides a method for manufacturing a semiconductor package, including manufacturing a sub-package, arranging the sub-package on a first redistribution structure, molding the sub-package with a first encapsulant, forming a conductive post on the first encapsulant, arranging a first semiconductor chip on the first encapsulant, molding the conductive post and the first semiconductor chip with a second encapsulant, and forming a second redistribution structure on the second encapsulant, wherein the manufacturing of the sub-package includes preparing a frame having a through hole, arranging a second semiconductor chip in a frame of the through hole, molding the second semiconductor chip with a third encapsulant, forming a third redistribution structure on the second semiconductor chip and the frame, and forming a fourth redistribution structure on the third encapsulant.

According to embodiments of the present disclosure, a semiconductor package capable of improving product yield and productivity and a package-on-package device including the same may be provided.

According to embodiments of the present disclosure, a semiconductor package capable of preventing or reducing defects in the conductive post and a package-on-package device including the same may be provided.

### BRIEF DESCRIPTION OF THE DRAWINGS

FIG. 1 is a cross-sectional view of a semiconductor package according to an embodiment.

FIG. 2 is an enlarged cross-sectional view of a second semiconductor chip of the semiconductor package illustrated in FIG. 1.

FIG. 3 is an enlarged cross-sectional view of a first semiconductor chip of the semiconductor package illustrated in FIG. 1.

FIG. 4 is a cross-sectional view of the semiconductor package according to another embodiment.

FIG. 5 is a cross-sectional view of the semiconductor package according to another embodiment.

FIG. 6 is a cross-sectional view of the semiconductor package according to another embodiment.

FIG. 7 is a cross-sectional view of the semiconductor package according to another embodiment.

FIG. 8 is a cross-sectional view of a package-on-package including the semiconductor package illustrated in FIG. 1.

FIGS. 9 to 29 are cross-sectional views sequentially showing a method for manufacturing the semiconductor package illustrated in FIG. 1.

### DETAILED DESCRIPTION OF THE EMBODIMENTS

The present disclosure will be described in detail hereinafter with reference to the accompanying drawings, in which embodiments of the present disclosure are shown. As those skilled in the art would realize, the described embodiments may be modified in various different ways, all without departing from the spirit or scope of the present disclosure and/or the present invention.

The drawings and description are to be regarded as illustrative in nature and not restrictive, and like reference numerals designate like elements throughout the specification.

Further, since sizes and thicknesses of components shown in the accompanying drawings may be arbitrarily given to facilitate understanding and ease of description, the disclosure is not limited to the illustrated sizes and thicknesses. In the drawings, the thickness of layers, films, panels, regions, etc., are exaggerated for clarity. In the drawings, to facilitate understanding and ease of description, the thicknesses of some layers and regions may be exaggerated.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

It should be understood that when an element such as a layer, film, region, or substrate is referred to as being “on” another element, it may be directly on the other element or intervening elements may also be present. In contrast, when an element is referred to as being “directly on” another element, there are no intervening elements present. Further, being “on” a reference element means being above or below the reference element, and it may not necessarily mean being disposed “above” it in a direction opposite to gravity.

In addition, unless explicitly described to the contrary, the word “comprise,” and variations such as “comprises” and “comprising,” should be understood to imply the inclusion of stated elements but not the exclusion of any other elements. Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

In addition, the phrase “in a plan view” means viewing the object from the top, and the phrase “in a cross-section” (or “in a cross sectional view) means viewing a vertical cross-section of a target portion from the side, unless context indicates otherwise.

In addition, throughout the specification, although the terms “first,” “second,” and the like are used to explain various components, the components are not limited to such terms but are only used to distinguish one component from another component. Accordingly, a configuration referred to as the first component in a certain part of the specification may also be referred to as the second component in other parts of the specification.

As used herein, singular forms are intended to include plural forms unless the context clearly indicates otherwise. For example, “an insulating layer” may be used to mean not only a single insulating layer (e.g., a single continuous layer formed of the same base layer throughout), but also a composite layer including a plurality of insulating layers, such as two, three, or more.

Items described in the singular herein may be provided in plural, as can be seen, for example, in the drawings. Thus, the description of a single item that is provided in plural should be understood to be applicable to the remaining plurality of items unless context indicates otherwise.

In addition, throughout the specification, references to one surface and another surface are intended to distinguish different surfaces from each other, and are not necessarily intended to limit them to a specific surface. Accordingly, the side referred to as one surface in a specific part of this specification may be referred to as the other surface in other parts of this specification.

Additionally, throughout the specification, references to directions such as upper surface, upper side, upper part, lower surface, lower side, and lower part are intended to aid description and understanding with reference to the drawings.

Terms such as “coplanar,” “same,” “equal,” “constant,” “flat,” etc. as used herein, are intended to encompass meanings that include typical variations resulting from conventional manufacturing processes and/or accommodate tolerances acceptable in the manufacturing process of the semiconductor device, unless the context or other statements indicate otherwise. For example, ‘same’ and ‘equal’ may encompass identicality or near identicality. The term “substantially” may be used herein to emphasize this meaning.

Hereinafter, a semiconductor package and a package-on-package according to embodiments of the present disclosure will be described with reference to the drawings.

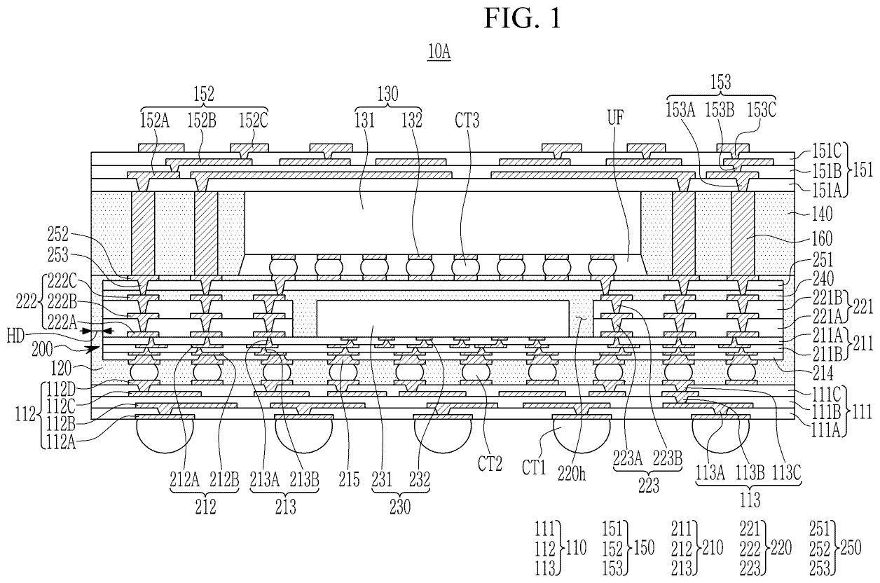

FIG. 1 is a cross-sectional view of a semiconductor package according to an embodiment.

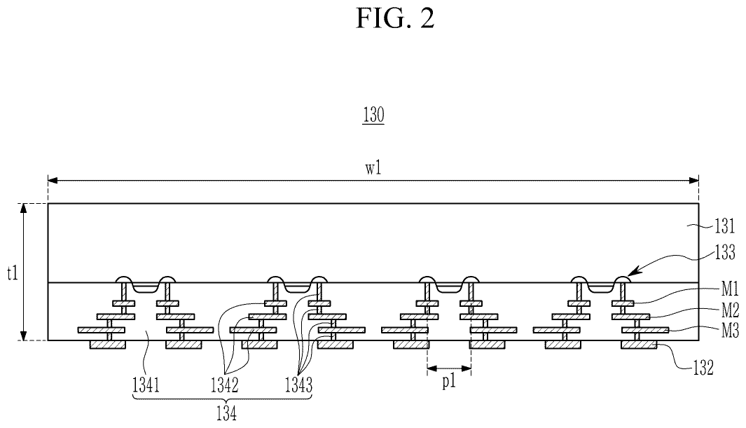

FIG. 2 is an enlarged cross-sectional view of a second semiconductor chip of the semiconductor package illustrated in FIG. 1.

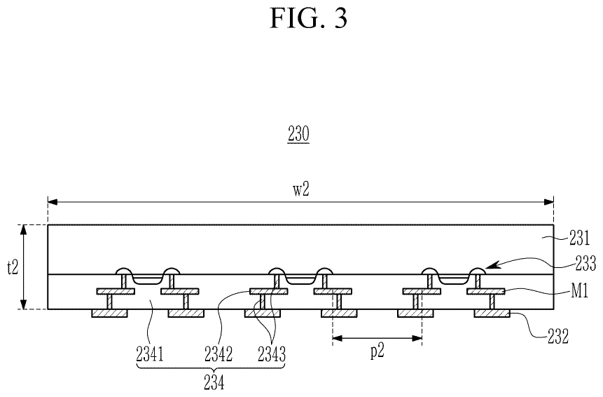

FIG. 3 is an enlarged cross-sectional view of a first semiconductor chip of the semiconductor package illustrated in FIG. 1.

Referring to FIG. 1, a semiconductor package 10A according to an embodiment includes a first redistribution structure 110, a sub-package 200 disposed on the first redistribution structure 110, a second encapsulant 120 covering at least a portion of the sub-package 200, a second semiconductor chip 130 disposed on the second encapsulant 120, a third encapsulant 140 covering at least a portion of the second semiconductor chip 130, a fourth redistribution structure 150 disposed on the third encapsulant 140, and a conductive post 160 embedded in the third encapsulant 140 and electrically connecting the sub-package 200 and the fourth redistribution structure 150. Additionally, the sub-package 200 includes a second redistribution structure 210, a frame 220 having a through hole 220h, a first semiconductor chip 230 disposed within the through hole 220h, a first encapsulant 240 filling at least a portion of the through hole 220h and covering at least a portion of the first semiconductor chip 230, and a third redistribution structure 250 disposed on the first encapsulant 240. For example, the conductive post 160 may be spaced apart from the first redistribution structure 110.

For example, each of the redistribution structures (or interconnection layers), throughout the specification, may be a composite layer which includes sub-layers and/or patterns. For example, the frame 220 (or apertured interconnection layer, intermediate interconnection pattern, or intermediate redistribution pattern), throughout the specification, may be a composite layer (or a composite pattern) which includes sub-layers and/or patterns.

The first redistribution structure 110 may redistribute the sub-package 200 and the second semiconductor chip 130. For example, throughout the specification, redistribution structures may be interconnection layers each of which reroutes electrical signals from/to a sub-package and/or a semiconductor chip, redistributing them to designated locations. The first redistribution structure 110 may include an insulating layer 111, a wiring layer 112, and a via 113. For example, the insulating layer 111 may include a first insulating layer 111A, a second insulating layer 111B, and a third insulating layer 111C. For example, the wiring layer 112 may include a first wiring layer 112A, a second wiring layer 112B, a third wiring layer 112C, and a fourth wiring layer 112D. For example, the via 113 may include a first via 113A, a second via 113B, and a third via 113C.

For example, the first redistribution structure 110 includes the first wiring layer 112A, the first insulating layer 111A covering the first wiring layer 112A, the second wiring layer 112B disposed on the first insulating layer 111A, the first via 113A penetrating the first insulating layer 111A and electrically connecting the first wiring layer 112A and the second wiring layer 112B, the second insulating layer 111B disposed on the first insulating layer 111A and covering the second wiring layer 112B, the third wiring layer 112C disposed on the second insulating layer 111B, the second via 113B penetrating the second insulating layer 111B and electrically connecting the second wiring layer 112B and the third wiring layer 112C, the third insulating layer 111C disposed on the second insulating layer 111B and covering the third wiring layer 112C, the fourth wiring layer 112D disposed on the third insulating layer 111C, and the third via 113C penetrating the third insulating layer 111C and electrically connecting the third wiring layer 112C and the fourth wiring layer 112D. However, the number of layers of the first redistribution structure 110 may be less or more than that shown in the drawings. For example, the first redistribution structure 110 may include fewer or more wiring and/or insulating layers than illustrated in the drawings.

An insulating material may be used as the material for the insulating layer 111. For example, the insulating layer 111 may include a thermoplastic resin such as polyimide (PI), a thermosetting resin such as epoxy, polybenzoxazole (PBO), or benzocyclobutene (BCB), or a resin in which these resins are mixed with an inorganic filler (e.g., an Ajinomoto build-up film (ABF)). In some embodiments, the insulating layer 111 may include a photo-imageable dielectric (PID) that is capable of being patterned by a photolithography process. For example, the insulating layer 111 may include photosensitive polyimide (PSPI). When the insulating layer 111 includes the PID, a fine pitch may be implemented through formation of a photo via. For example, where the insulating layer 111 is formed of a PID, a plurality of vias having a fine pitch may be formed therein. When the insulating layer 111 is multi-layered, the material of each insulating layer 111 may be the same or different. For example, where the insulating layer 111 comprises a plurality of sublayers (e.g., the first insulating layer 111A, the second insulating layer 111B, and the third insulating layer 111C), respective sublayers may be formed of the same material or different materials. When the insulating layer 111 is multi-layered, the insulating layers 111 may have boundaries with each other, may have unclear boundaries, or may be integrated and have no boundaries. For example, where the insulating layer 111 comprises multiple sublayers, adjacent sublayers may have sharply defined boundaries, partially distinct (e.g., diffused, graded or intermixed) boundaries, or no boundaries (e.g., integrated into a single continuous body).

Each of the sublayers (e.g., the first wiring layer 112A, the second wiring layer 112B, the third wiring layer 112C, and the fourth wiring layer 112D) of the wiring layer 112 may be disposed on a corresponding one (or corresponding pair) of the sublayers of the insulating layer 111. The wiring layer 112 may include a wiring pattern (e.g., a signal pattern, a power pattern, a ground pattern, etc.), a via pad for connection to the via 113, a connection pad for electrical connection to other components (e.g., the connection pad may be included in the uppermost wiring layer 112D and/or the lowermost wiring layer 112A), etc. A conductive material may be used as the material for the wiring layer 112. For example, the wiring layer 112 may include a metal such as aluminum (Al), copper (Cu), titanium (Ti), tungsten (W), gold (Au), platinum (Pt), silver (Ag), tin (Sn), chromium (Cr), palladium (Pd), or an alloy of two or more of these.

Each via 113 penetrates at least one of the insulating layers 111 and may physically and/or electrically connect the wiring layers 112 disposed in different layers (or vertical levels). The via 113 may have various shapes, such as a tapered shape with a width that narrows from one side (e.g., top portion) to the other side (e.g., bottom portion), or a cylindrical shape. A conductive material may be used as the material for the via 113. For example, the via 113 may include a metal such as aluminum (Al), copper (Cu), titanium (Ti), tungsten (W), gold (Au), platinum (Pt), silver (Ag), tin (Sn), chromium (Cr), palladium (Pd), or an alloy of two or more of these. The via 113 may have the interior of a via hole completely filled with a conductive material, or a conductive material may be formed along a wall and the bottom surface of the via hole. For example, the via 113 may be configured as a solid via, with a via hole being substantially fully filled with a conductive material. For example, the via 113 may be implemented as a partially filled via, with a conformal conductive lining on the sidewalls and bottom of the via hole. The via 113 may be formed integrally with the wiring layer 112 disposed on the upper side thereof. For example, one of the vias 113 and a corresponding one (or corresponding pair) of the wiring layers 112 may be formed of the same material without a boundary interface therebetween, and may form a single continuous body. For example, the via 113 and the wiring layer 112 may be formed by forming a via hole penetrating the insulating layer 111 and filling the via hole with a conductive material to fill the via hole and extend over the insulating layer 111. The via 113 and the wiring layer 112 may include a first conductive layer functioning as a seed layer and a second conductive layer disposed on the first conductive layer. The first conductive layer may extend along the surface of the insulating layer 111, the wall, and the bottom surface of the via hole.

A first connection terminal CT1 for physically and/or electrically connecting the semiconductor package 10A to another component (e.g., a main board) may be disposed on the lower surface of the first redistribution structure 110. The first connection terminals CT1 may provide (or be configured as) a ball grid array, a land grid array, or a pin grid array. A conductive material may be used as the material for the first connection terminal CT1. For example, the first connection terminal CT1 may be a solder ball including solder formed of an Sn—Ag alloy, an Sn—Ag—Cu alloy, or the like. Alternatively, the first connection terminal CT1 may include a metal or an alloy of metals. There are no particular restrictions on the size, number, spacing, arrangement, etc. of the first connection terminal CT1.

The sub-package 200 may be disposed on the first redistribution structure 110 and electrically connected to the first redistribution structure 110. The second semiconductor chip 130 and the conductive post 160 are disposed on the sub-package 200, and the width of the sub-package 200 may be wider than the width of the second semiconductor chip 130 in a horizontal direction which is parallel to the upper surface of the first redistribution structure 110.

The sub-package 200 may include the second redistribution structure 210, the frame 220 having the through hole 220h, the first semiconductor chip 230 disposed within the through hole 220h, the first encapsulant 240 filling at least a portion of the through hole 220h and covering at least a portion of the first semiconductor chip 230, and the third redistribution structure 250 disposed on the first encapsulant 240. The sub-package 200 may be manufactured, for example, using a panel level packaging (PLP) process. The sub-package 200 may be a fan-out type package, and the second redistribution structure 210 and the third redistribution structure 250 may extend to the outside including the foot print of the first semiconductor chip 230 in a plan view. For example, the second redistribution structure 210 and the third redistribution structure 250 may horizontally extend beyond the first semiconductor chip 230 in a plan view.

The second redistribution structure 210 is electrically connected to the first semiconductor chip 230 and may rewire (or reroute an electrical signal from/to) a connection pad 232 of the first semiconductor chip 230. The second redistribution structure 210 may have a configuration that is similar to, or substantially identical to, the configuration of the first redistribution structure 110. For example, the second redistribution structure 210 may include an insulating layer 211, a wiring layer 212, and a via 213. For example, the second redistribution structure 210 may include a first insulating layer 211A, a first wiring layer 212A disposed on the lower surface of the first insulating layer 211A, a first via 213A penetrating the first insulating layer 211A and electrically connecting the first wiring layer 212A and the frame 220, a second insulating layer 211B disposed on the first insulating layer 211A and covering the first wiring layer 212A, a second wiring layer 212B disposed on the lower surface of the second insulating layer 211B, and a second via 213B penetrating the second insulating layer 211B and electrically connecting the second wiring layer 212B and the first wiring layer 212A. However, the number of layers of the second redistribution structure 210 may be less or more than that shown in the drawings.

An insulating material may be used as the material for the insulating layer 211. For example, the insulating layer 211 may include a thermoplastic resin such as polyimide (PI), a thermosetting resin such as epoxy, polybenzoxazole (PBO), or benzocyclobutene (BCB), or a resin in which these resins are mixed with an inorganic filler (e.g., the Ajinomoto build-up film (ABF)). In some embodiments, the insulating layer 211 may include the photo-imageable dielectric (PID) that is capable of being patterned by a photolithographic process. For example, the insulating layer 211 may include photosensitive polyimide (PSPI). When the insulating layer 211 includes the PID, a fine pitch may be implemented through formation of a photo via. When the insulating layer 211 is multi-layered, the material of each insulating layer 211 may be the same or different. When the insulating layer 211 is multi-layered, the insulating layers 211 may have boundaries with each other, may have unclear boundaries, or may be integrated and have no boundaries.

Each of the wiring layers 212 may be disposed on a corresponding one (or corresponding pair) of the insulating layers 211. The wiring layer 212 may include a wiring pattern (e.g., a signal pattern, a power pattern, a ground pattern, etc.), a via pad for connection to the via 213, a connection pad for electrical connection to other components (e.g., may be included in a lowermost wiring layer 212B), etc. A conductive material may be used as the material for the wiring layer 212. For example, the wiring layer 212 may include a metal such as aluminum (Al), copper (Cu), titanium (Ti), tungsten (W), gold (Au), platinum (Pt), silver (Ag), tin (Sn), chromium (Cr), palladium (Pd), or an alloy of two or more of these. The wiring layer 212 may have a smaller pitch than wiring layers 222 and 252 of the frame 220 and the third redistribution structure 250, but it is not limited thereto.

Each via 213 penetrates at least one of the insulating layers 211 and may physically and/or electrically connect the wiring layers 212 disposed in different layers (or vertical levels). Some of the vias 213—for example, the uppermost via 213A—may electrically connect the wiring layer 212 to the wiring layer 222 of the frame 220. The via 213 may have various shapes, such as a tapered shape with a width that narrows from one side to the other side, or a cylindrical shape. A conductive material may be used as the material for the via 213. For example, the via 213 may include a metal such as aluminum (Al), copper (Cu), titanium (Ti), tungsten (W), gold (Au), platinum (Pt), silver (Ag), tin (Sn), chromium (Cr), palladium (Pd), or an alloy of two or more of these. The via 213 may be formed by completely filling a via hole with a conductive material, or by conformally forming a conductive material along the wall and the bottom surface of the via hole. The via 213 may be formed integrally with the wiring layer 212 located on the lower side thereof. For example, the via 213 and the wiring layer 212 may be formed by forming a via hole penetrating the insulating layer 211 and filling the via hole with a conductive material to fill the via hole and extend over the insulating layer 211. The via 213 and the wiring layer 212 may include the first conductive layer functioning as a seed layer and a second conductive layer disposed on the first conductive layer. The first conductive layer may extend along the surface of the insulating layer 211, the wall, and the bottom surface of the via hole. The wiring layer 212 may have a smaller pitch than vias 223 and 253 of the frame 220 and the third redistribution structure 250, but it is not limited thereto.

At least one of a passivation layer 214, an under bump metallization layer 215, and a second connection terminal CT2 may be additionally disposed on the lower surface of the second redistribution structure 210.

The passivation layer 214 is disposed on the lower surface of the second redistribution structure 210 and may have an opening that exposes at least a portion of the lowermost wiring layer 212B that functions as a connection pad. The passivation layer 214 may be in contact with the lowermost insulating layer 211B of the second redistribution structure 210. An insulating material may be used as the material for the passivation layer 214. For example, the passivation layer 214 may include at least one of the materials listed as materials of the insulating layer 211 of the second redistribution structure 210.

An under bump metal layer 215 physically and/or electrically connects the second redistribution structure 210 and the second connection terminal CT2, and may prevent or reduce cracks in the second connection terminal CT2 and improve connection reliability. The under bump metal layer 215 is disposed on the lower surface of the second redistribution structure 210 and may fill at least a portion of the opening of the passivation layer 214. The under bump metal layer 215 may include an under bump pad disposed on the lower surface of the passivation layer 214 and an under bump via penetrating the passivation layer 214 to connect the under bump pad and the lowermost wiring layer 212B of the second redistribution structure 210. Depending on the embodiment, the under bump via may be a plated via formed along the wall of the opening of the passivation layer 214 and the surface of the lowermost wiring layer 212B, but may also be a filled via that fills the opening of the passivation layer 214. Depending on the embodiment, the under bump pad may have a ring shape with an empty space in the center, but may also have a circular plate shape with a filled space in the center. A conductive material may be used as the material for the under bump metal layer 215. For example, the under bump metal layer 215 may include a metal such as aluminum (Al), copper (Cu), titanium (Ti), tungsten (W), gold (Au), platinum (Pt), silver (Ag), tin (Sn), chromium (Cr), palladium (Pd), or an alloy of two or more of these.

The second connection terminal CT2 for electrical connection between the sub-package 200 and the first redistribution structure 110 may be disposed. For example, the second connection terminal CT2 may be disposed between the under bump metal layer 215 of the sub-package 200 and the uppermost wiring layer 112D of the first redistribution structure 110 to electrically connect them. A conductive material may be used as the material for the second connection terminal CT2. For example, the second connection terminal CT2 may include a solder formed of an Sn—Ag alloy, an Sn—A—-Cu alloy, or the like. Alternatively, the second connection terminal CT2 may include a metal or an alloy of metals. The second connection terminal CT2 may include a single layer (e.g., a single continuous layer formed of the same base layer throughout) or multiple layers. In some embodiments, the second connection terminal CT2 may be a C4 bump. In some embodiments, the second connection terminal CT2 may be a pillar bump including a conductive pillar and a conductive cap disposed on the conductive pillar. Metals such as copper (Cu) and aluminum (Al) may be used as materials for the conductive pillar. Solder may be used as the material for the conductive cap. There are no particular restrictions on the size, number, spacing, arrangement, etc. of the second connection terminal CT2.

The frame 220 may be disposed on the second redistribution structure 210 and electrically connected to the second redistribution structure 210. The frame 220 may be in contact with the second redistribution structure 210. For example, the frame 220 may be disposed directly on the uppermost insulating layer 211A of the second redistribution structure 210 and may be electrically connected to the uppermost wiring layer 212A through the uppermost via 213A of the second redistribution structure 210. The frame 220 may include the wiring layer 222, which may improve the freedom of wiring design of the sub-package 200. In addition, the frame 220 includes a thick and rigid insulating layer 221, which may improve the rigidity of the sub-package 200. The thickness of the frame 220 may be equal to or similar to the thickness of the first semiconductor chip 230. For example, the frame 220 may have a thickness (in the vertical direction) greater than that of the second redistribution structure 210.

The frame 220 may have the through hole 220h penetrating the frame 220 in the thickness direction (the vertical direction). The through hole 220h may have an approximately (or substantially) square shape in a plan view. The first semiconductor chip 230 may be disposed to be spaced apart from the wall of the through hole 220h, and the frame 220 may surround the first semiconductor chip 230. The width of the through hole 220h may be wider than the width of the first semiconductor chip 230, in a horizontal direction. The width of the through hole 220h may be constant in the thickness direction or may narrow from one side to the other side. The method of forming the through hole 220h is not particularly limited, and it may be formed by laser processing, mechanical processing, etc.

The frame 220 may have a configuration that is similar to the configuration of the second redistribution structure 210 (or the first redistribution structure 110). For example, the frame 220 may include the insulating layer 221, the wiring layer 222, and a via 223. For example, the frame 220 may include a first wiring layer 222A, a first insulating layer 221A covering the first wiring layer 222A, a second wiring layer 222B disposed on the first insulating layer 221A, a first via 223A penetrating the first insulating layer 221A and electrically connecting the first wiring layer 222A and the second wiring layer 222B, a second insulating layer 221B disposed on the first insulating layer 221A and covering the second wiring layer 222B, a third wiring layer 222C disposed on the second insulating layer 221B, and a second via 223B penetrating the second insulating layer 221B and electrically connecting the second wiring layer 222B and the third wiring layer 222C. However, the number of layers of the frame 220 may be less or more than that shown in the drawings. The frame 220 may be an embedded trace substrate (ETS) in which the first wiring layer 222A is embedded in the first insulating layer 221A.

An insulating material may be used as the material for the insulating layer 221. For example, the insulating layer 221 may include a thermoplastic resin such as polyimide (PI), a thermosetting resin such as epoxy, a resin in which these resins are mixed with an inorganic filler, or a resin impregnated into glass fibers together with an inorganic filler (e.g., prepreg, FR-4, bismaleimide triazine (BT), etc.). When the insulating layer 221 is multi-layered, the material of each insulating layer 221 may be the same or different. When the insulating layer 221 is multi-layered, the insulating layers 221 may have boundaries with each other, may have unclear boundaries, or may be integrated and have no boundaries. Each insulating layer 221 may be thicker than the insulating layers 111, 211, 251, and 151 of the redistribution structures 110, 210, 250, and 150, but it is not limited thereto.

Each wiring layer 222 may be disposed on each insulating layer 221. However, among the wiring layers 222, the lowermost wiring layer 222A may be covered with the lowermost insulating layer 221A. For example, the lowermost insulating layer 221A may cover the upper surface and side surface of the lowermost wiring layer 222A, and the lower surface of the lowermost wiring layer 222A may be exposed at (or may be exposed beyond, or may terminate flush with) the lower surface of the lowermost insulating layer 221A. The lower surface of the lowermost wiring layer 222A may be coplanar with the lower surface of the lowermost insulating layer 221A. The wiring layer 222 may include a wiring pattern (e.g., a signal pattern, a power pattern, a ground pattern, etc.), a via pad for connection to the via 223, a connection pad for electrical connection to other components, etc. A conductive material may be used as the material for the wiring layer 222. For example, the wiring layer 222 may include a metal such as aluminum (Al), copper (Cu), titanium (Ti), tungsten (W), gold (Au), platinum (Pt), silver (Ag), tin (Sn), chromium (Cr), palladium (Pd), or an alloy of two or more of these.

Each via 223 penetrates at least one of the insulating layers 221 and may physically and/or electrically connect the wiring layers 212 disposed in different layers (or vertical levels). The via 223 may have various shapes, such as a tapered shape with a width that narrows from one side to the other side, a cylindrical shape, or an hourglass shape. A conductive material may be used as the material for the via 223. For example, the via 223 may include a metal such as aluminum (Al), copper (Cu), titanium (Ti), tungsten (W), gold (Au), platinum (Pt), silver (Ag), tin (Sn), chromium (Cr), palladium (Pd), or an alloy of two or more of these. The via 223 may be formed by completely filling a via hole with a conductive material, or by conformally forming a conductive material along the wall and the bottom surface of the via hole. The via 223 may be formed integrally with the wiring layer 112 disposed on the upper side thereof. For example, the via 223 and the wiring layer 222 may be formed by forming a via hole penetrating the insulating layer 221 and filling the via hole with a conductive material to fill the via hole and extend over the insulating layer 221. The via 223 and the wiring layer 222 may include the first conductive layer functioning as a seed layer and the second conductive layer disposed on the first conductive layer. The first conductive layer may extend along the surface of the insulating layer 221, the wall, and the bottom surface of the via hole.

The first semiconductor chip 230 may be disposed within the through hole 220h and electrically connected to the second redistribution structure 210. The first semiconductor chip 230 may be in contact with the second redistribution structure 210. For example, the first semiconductor chip 230 may be disposed directly on the uppermost insulating layer 211A of the second redistribution structure 210 and may be electrically connected to the uppermost wiring layer 212A through the uppermost via 213A of the second redistribution structure 210.

The first semiconductor chip 230 may include a semiconductor substrate 231, individual (or unit) elements 233 formed on a surface of the semiconductor substrate 231 (or formed with the semiconductor substrate 231), a wiring structure 234 disposed on the semiconductor substrate 231 and electrically connected to the individual elements 233, and a first connection pad 232 disposed on the wiring structure 234 and electrically connected to the wiring structure 234. The semiconductor substrate 231 may include a semiconductor material. For example, the semiconductor substrate 231 may include a semiconductor element such as silicon (Si), germanium (Ge), or a compound semiconductor such as gallium arsenide (GaAs), indium arsenide (InAs), or silicon carbide (SiC). The semiconductor substrate 231 may have a shape that is approximately quadrangular—for example, a square or a rectangle—but is not limited thereto. The individual elements 233 may include, for example, at least one of a metal-oxide-semiconductor field effect transistor (MOSFET), a bipolar junction transistor (BJT), a fin field effect transistor (FinFET), a gate all around (GAA), a diode, a capacitor, and a resistor. The wiring structure 234 may include an insulating layer 2341, a wiring layer 2342, and a via 2343. The insulating layer 2341 may include an inorganic insulating material such as silicon oxide, silicon nitride, or silicon carbide nitride (SiCN), and/or an organic insulating material such as polyimide (PI), polybenzoxazole (PBO), or benzocyclobutene (BCB). Although the wiring layer 2342 is illustrated as including only a first layer M1 in the drawing, the wiring layer 2342 may include a greater number of layers. The wiring layer 2342 and the via 2343 may include a conductive material such as copper (Cu) or aluminum (Al). The first connection pad 232 may electrically connect the first semiconductor chip 230 to the second redistribution structure 210. A conductive material may be used as the material for the first connection pad 232. For example, the first connection pad 232 may include a metal such as aluminum (Al), copper (Cu), titanium (Ti), tungsten (W), gold (Au), platinum (Pt), silver (Ag), tin (Sn), chromium (Cr), palladium (Pd), or an alloy of two or more of these. The surface of the first semiconductor chip 230 on which the first connection pad 232 of the first semiconductor chip 230 is disposed may be referred to as an active surface, and the surface opposite to (or facing away from) the active surface may be referred to as an inactive surface. The first semiconductor chip 230 may be disposed in a face-down configuration so that the active surface faces the second redistribution structure 210. However, the first semiconductor chip 230 may be disposed in a face-up configuration so that the active surface faces the third redistribution structure 250, and in this embodiment, the first connection pad 232 may be electrically connected to the via 253 of the third redistribution structure 250.

The first semiconductor chip 230 may include (or be) a logic chip. The logic chip may include a logic circuit, and may include (or be), for example, at least one of an application processor (AP), a microprocessor, a central processing unit (CPU), a graphic processing unit (GPU), a neural processing unit (NPU), an application-specific integrated circuit (ASIC), a system on chip (SoC), a physical layer (PHY), a modulator-demodulator (modem), a power management integrated circuit (PMIC), and a display driver IC (DDI).

The first encapsulant 240 may fill at least a portion of the through hole 220h and cover at least a portion of the first semiconductor chip 230. For example, the first encapsulant 240 may fill at least a portion of the space between the wall of the through hole 220h and the side surface of the first semiconductor chip 230, and cover the upper surface and the side surface of the first semiconductor chip 230. Additionally, the first encapsulant 240 may extend onto the upper surface of the frame 220. An insulating material may be used as the material for the first encapsulant 240. For example, the first encapsulant 240 may include an epoxy molding compound (EMC). Alternatively, the first encapsulant 240 may include a thermoplastic resin such as polyimide (PI), a thermosetting resin such as epoxy, or a resin in which these resins are mixed with an inorganic filler such as SiO₂ (e.g., the Ajinomoto build-up film (ABF)). Alternatively, the first encapsulant 240 may include the photo-imageable dielectric (PID), such as photosensitive polyimide (PSPI).

The third redistribution structure 250 may be disposed on the first encapsulant 240 and electrically connected to the frame 220. Some regions (e.g., lower regions) or portions of the vias 253 of the third redistribution structure 250 may extend into the first encapsulant 240 covering the upper surface of the frame 220.

The third redistribution structure 250 may have a configuration that is similar to, or substantially identical to, the configuration of the first and second redistribution structures 110 and 210. For example, the third redistribution structure 250 may include an insulating layer 251, a wiring layer 252, and the via 253. In some embodiments, the third redistribution structure 250 may be formed as a single layer (e.g., a single continuous layer formed of the same base layer throughout) and may include the insulating layer 251 disposed on the first encapsulant 240, the wiring layer 252 disposed on the insulating layer 251, and the via 253 penetrating the insulating layer 251 and extending into the first encapsulant 240 to electrically connect the wiring layer 252 and the frame 220. By introducing (or utilizing) the insulating layer 251 on the first encapsulant 240, the quality of a surface planarization process and other processes may be improved, and the bonding strength with a third connection terminal CT3 may be improved (or increased) by increasing the planar size of the wiring layer 252 that functions as the via 253 and a connection pad. The wiring layer 252 may be formed directly on the first encapsulant 240, and in this embodiment, the third redistribution structure 250 may not include the insulating layer 251, and the via 253 may be embedded in the first encapsulant 240.

An insulating material may be used as the material for the insulating layer 251. For example, the insulating layer 251 may include a thermoplastic resin such as polyimide (PI), a thermosetting resin such as epoxy, polybenzoxazole (PBO), or benzocyclobutene (BCB), or a resin in which these resins are mixed with an inorganic filler (e.g., the Ajinomoto build-up film (ABF)). In some embodiments, the insulating layer 251 may include the photo-imageable dielectric (PID) that is capable of being patterned by a photolithographic process.

The wiring layer 252 is disposed on the insulating layer 251 and may be exposed at (or may be exposed beyond, or may terminate flush with) the upper surface of the second encapsulant 120. The upper surface of the wiring layer 252 and the upper surface of the second encapsulant 120 may be coplanar. The wiring layer 252 may include a wiring pattern (e.g., a signal pattern, a power pattern, a ground pattern, etc.), a via pad for connection to the via 253, a connection pad for electrical connection to other components, etc. A conductive material may be used as the material for the wiring layer 252. For example, the wiring layer 252 may include a metal such as aluminum (Al), copper (Cu), titanium (Ti), tungsten (W), gold (Au), platinum (Pt), silver (Ag), tin (Sn), chromium (Cr), palladium (Pd), or an alloy of two or more of these.

The via 253 penetrates the insulating layer 251 and extends into the first encapsulant 240, and may physically and/or electrically connect the wiring layer 252 and the uppermost wiring layer 222C of the frame 220. The via 253 may have various shapes, such as a tapered shape with a width that narrows from one side to the other side, or a cylindrical shape. A conductive material may be used as the material for the via 253. For example, the via 253 may include a metal such as aluminum (Al), copper (Cu), titanium (Ti), tungsten (W), gold (Au), platinum (Pt), silver (Ag), tin (Sn), chromium (Cr), palladium (Pd), or an alloy of two or more of these. The via 253 may be formed by completely filling a via hole with a conductive material, or by conformally forming a conductive material along the wall and the bottom surface of the via hole. The via 253 may be formed integrally with the wiring layer 252. For example, the via 253 and the wiring layer 252 may be formed by forming a via hole that penetrates the insulating layer 251 and extends into the first encapsulant 240, and filling the via hole with a conductive material to fill the via hole and extend over the insulating layer 251. The via 253 and the wiring layer 252 may include the first conductive layer functioning as a seed layer and the second conductive layer disposed on the first conductive layer. The first conductive layer may extend along the surface of the insulating layer 251, the wall, and the bottom surface of the via hole.

The second encapsulant 120 may cover at least a portion of the sub-package 200. For example, the second encapsulant 120 may cover the side surface of the sub-package 200 and extend onto the insulating layer 251 of the third redistribution structure 250 to cover the upper surface of the insulating layer 251 and the side surface of the wiring layer 252. The components disposed on the side surface of the sub-package 200 and covered with the second encapsulant 120 may be the frame 220, the second redistribution structure 210, and the third redistribution structure 250. Additionally, the second encapsulant 120 may fill at least a portion of the space between the sub-package 200 and the first redistribution structure 110. An insulating material may be used as the material for the second encapsulant 120. For example, the second encapsulant 120 may include the epoxy molding compound (EMC). Alternatively, the second encapsulant 120 may include a thermoplastic resin such as polyimide (PI), a thermosetting resin such as epoxy, or a resin in which these resins are mixed with an inorganic filler such as SiO₂ (e.g., the Ajinomoto build-up film (ABF)). Alternatively, the second encapsulant 120 may include the photo-imageable dielectric (PID), such as photosensitive polyimide (PSPI).

The second semiconductor chip 130 is disposed on the second encapsulant 120 and may be electrically connected to the third redistribution structure 250 of the sub-package 200. For example, the second semiconductor chip 130 may be electrically connected to the wiring layer 252 exposed at (or may be exposed beyond, or may terminate flush with) the upper surface of the second encapsulant 120. In some embodiments, the upper surface of the second semiconductor chip 130 may be exposed at the upper surface of the third encapsulant 140. The upper surface of the second semiconductor chip 130 may be coplanar with the upper surface of the third encapsulant 140. The upper surface of the second semiconductor chip 130 exposed at the upper surface of the third encapsulant 140 may be in contact with the fourth redistribution structure 150. For example, the second semiconductor chip 130 may be in contact with a lowermost insulating layer 151A of the fourth redistribution structure 150. However, the upper surface of the second semiconductor chip 130 may be covered with the third encapsulant 140.

The second semiconductor chip 130 may include a semiconductor substrate 131, individual (or unit) elements 133 formed on the surface of the semiconductor substrate 131 (or formed with the semiconductor substrate 131), a wiring structure 134 disposed on the semiconductor substrate 131 and electrically connected to the individual elements 133, and a connection pad 132 disposed on the wiring structure 134 and electrically connected to the wiring structure 134. The semiconductor substrate 131 may include a semiconductor material. For example, the semiconductor substrate 131 may include a semiconductor element such as silicon (Si), germanium (Ge), or a compound semiconductor such as gallium arsenide (GaAs), indium arsenide (InAs), or silicon carbide (SiC). The semiconductor substrate 131 may have a shape that is approximately quadrangle shape, for example, a square or a rectangle shape, but it is not limited thereto. The individual elements 133 may include, for example, at least one of a metal-oxide-semiconductor field effect transistor (MOSFET), a bipolar junction transistor (BJT), a fin field effect transistor (FinFET), a gate-all-around (GAA), a diode, a capacitor, and a resistor. The wiring structure 134 may include an insulating layer 1341, a wiring layer 1342, and a via 1343. The insulating layer 1341 may include an inorganic insulating material such as silicon oxide, silicon nitride, or silicon carbide nitride (SiCN), and/or an organic insulating material such as polyimide (PI), polybenzoxazole (PBO), or benzocyclobutene (BCB). Although the wiring layer 1342 is illustrated as including only the first layer M1, a second layer M2, and a third layer M3 in the drawing, the wiring layer 1342 may include a greater number of layers. The wiring layer 1342 and the via 1343 may include a conductive material such as copper (Cu) or aluminum (Al). The connection pad 132 may electrically connect the second semiconductor chip 130 to the third redistribution structure 250. A conductive material may be used as the material for the connection pad 132. For example, the connection pad 132 may include a metal such as aluminum (Al), copper (Cu), titanium (Ti), tungsten (W), gold (Au), platinum (Pt), silver (Ag), tin (Sn), chromium (Cr), palladium (Pd), or an alloy of two or more of these. The surface of second semiconductor chip 130 on which the connection pad 132 of the second semiconductor chip 130 is disposed may be referred to as an active surface, and the surface opposite to (or facing away from) the active surface may be referred to as an inactive surface. The second semiconductor chip 130 may be disposed in a face-down configuration so that the active surface faces the third redistribution structure 250.

The second semiconductor chip 130 may include a (or be) logic chip. The logic chip may include a logic circuit, and may include (or be), for example, at least one of an application processor (AP), a microprocessor, a central processing unit (CPU), a graphic processing unit (GPU), a neural processing unit (NPU), an application-specific integrated circuit (ASIC), a system on chip (SoC), a physical layer (PHY), a modulator-demodulator (modem), a power management integrated circuit (PMIC), and a display driver IC (DDI).

In some embodiments, to improve product yield and/or to reduce manufacturing cost, the second semiconductor chip 130 may be fabricated on a leading-edge process node (e.g., a single-digit-nanometer node), and the first semiconductor chip 230 may be fabricated on non-leading-edge node. For example, the process node of the second semiconductor chip 130 may be smaller than the process node of the first semiconductor chip 230. For example, the second semiconductor chip 130 may include (or be) the CPU and/or the GPU, and the first semiconductor chip 230 may include (or be) the PHY and/or the modem.

The size of the individual elements 133 of the second semiconductor chip 130, which is fabricated on a leading-edge process node, may be smaller than the size of the individual elements 233 of the first semiconductor chip 230. Additionally, the pitch of the individual elements 133 of the second semiconductor chip 130 may be narrower (or smaller) than the pitch of the individual elements 233 of the first semiconductor chip 230. Here, the pitch of individual elements refers to the center-to-center distance between the centers of adjacent individual elements. Additionally, the integration density of the individual elements 133 of the second semiconductor chip 130 may be higher than the integration density of the individual elements 233 of the first semiconductor chip 230.

The wiring structure 134 of the second semiconductor chip 130 may have a smaller minimum wiring pitch (or minimum feature size) than that of the wiring structure 234 of the first semiconductor chip 230. For example, a wiring pitch p1 of the second semiconductor chip 130 may be narrower than a wiring pitch p2 of the first semiconductor chip 230. Here, the wiring pitch refers to the distance between the centers of adjacent wiring patterns in each wiring layer. As characterization of the differences between the leading-edge node and the non-leading-edge node, the wiring pitch p1 of the second semiconductor chip 130 and the wiring pitch p2 of the first semiconductor chip 230 may be compared with the minimum pitch—e.g., the distance between the centers of the most densely disposed wiring patterns. For example, the minimum wiring pitch may be the distance between the centers of the most densely disposed wiring patterns. As characterization of the differences between the leading-edge node and the non-leading-edge node, the wiring pitches (or minimum wiring pitches) p1 and p2 of the second semiconductor chip 130 and the first semiconductor chip 230 may be compared. The first layer M1 having the wiring pitch p1 may be a wiring layer closest to the individual elements 133 in the second semiconductor chip 130, and the first layer M1 having the wiring pitch p2 may be a wiring layer closest to the individual elements 233 in the first semiconductor chip 230. For example, in the drawings, the wiring pitches p1 and p2 are shown based on the first layer M1 that is closest to the individual elements 133 and 233 among the wiring layers M1, M2, and M3 of the first semiconductor chip 230 and the second semiconductor chip 130. Additionally, the number of layers of the wiring layer 1342 of the second semiconductor chip 130 may be greater than the number of layers of the wiring layer 2342 of the first semiconductor chip 230. In such configuration, a minimum wiring pitch p1 of the first layer M1 (that is closest to the individual elements 133) of the second semiconductor chip 130 may be smaller than a minimum wiring pitch p2 of the first layer M1 (that is closest to the individual elements 233) of the first semiconductor chip 230.

The width w1 (in a horizontal direction) of the second semiconductor chip 130 may be wider than the width w2 (in the horizontal direction) of the first semiconductor chip 230. The second semiconductor chip 130 has excellent performance and various functions, and may be larger than the first semiconductor chip 230 in a plan view. A thickness t1 of the second semiconductor chip 130 may be thicker than a thickness t2 of the first semiconductor chip 230. The second semiconductor chip 130 may be a heat-generating chip, and the heat dissipation characteristics may be improved by thickening the second semiconductor chip 130.

The second semiconductor chip 130 may be physically and/or electrically connected to the third redistribution structure 250 of the sub-package 200 through the third connection terminals CT3. The third connection terminal CT3 may be disposed, for example, between the connection pad 132 of the second semiconductor chip 130 and the wiring layer 252 of the third redistribution structure 250 to electrically connect them. A conductive material may be used as the material for the third connection terminal CT3. For example, the third connection terminal CT3 may include a solder formed of an Sn—Ag alloy, an Sn—Ag—Cu alloy, or the like. Alternatively, the third connection terminal CT3 may include a metal or an alloy of metals. The third connection terminal CT3 may include a single layer (e.g., a single continuous layer formed of the same base layer throughout) or multiple layers. In some embodiments, the third connection terminal CT3 may be a C4 bump. In some embodiments, the third connection terminal CT3 may be a pillar bump including a conductive pillar and a conductive cap disposed on the conductive pillar. Metals such as copper (Cu) and aluminum (Al) may be used as materials for the conductive pillar. Solder may be used as the material for the conductive cap. There are no particular restrictions on the size, number, spacing, arrangement, etc. of the third connection terminal CT3.

The third connection terminals CT3 may be covered with an underfill material UF that fills at least a portion of the space between the second encapsulant 120 and the second semiconductor chip 130. The underfill material UF may extend onto the lower side surface of the second semiconductor chip 130. The underfill material UF may include an insulating material such as epoxy resin, and may further include an inorganic filler such as silica or alumina, if necessary.

The third encapsulant 140 may cover at least a portion of each of the second semiconductor chip 130 and the conductive post 160. For example, the third encapsulant 140 may cover each side surface of the second semiconductor chip 130 and the conductive post 160. An insulating material may be used as the material for the third encapsulant 140. For example, the third encapsulant 140 may include an epoxy molding compound (EMC). Alternatively, the third encapsulant 140 may include a thermoplastic resin such as polyimide (PI), a thermosetting resin such as epoxy, or a resin in which these resins are mixed with an inorganic filler such as SiO₂ (e.g., the Ajinomoto build-up film (ABF)). Alternatively, the third encapsulant 140 may include a photo-imageable dielectric (PID), such as photosensitive polyimide (PSPI).

The fourth redistribution structure 150 is disposed on the third encapsulant 140 and may be electrically connected to the third redistribution structure 250 of the sub-package 200 through the conductive post 160. The fourth redistribution structure 150 may have a configuration that is similar to, or substantially identical to, the configuration of the first, second and third redistribution structure 110, 210 and 250. For example, the fourth redistribution structure 150 may include an insulating layer 151, a wiring layer 152, and a via 153. For example, the fourth redistribution structure 150 includes a first insulating layer 151A disposed on the third encapsulant 140, a first wiring layer 152A disposed on the first insulating layer 151A, a first via 153A penetrating the first insulating layer 151A and electrically connecting the first wiring layer 152A and the conductive post 160, a second insulating layer 151B disposed on the first insulating layer 151A and covering the first wiring layer 152A, a second wiring layer 152B disposed on the second insulating layer 151B, a second via 153B penetrating the second insulating layer 151B and electrically connecting the first wiring layer 152A and the second wiring layer 152B, a third insulating layer 151C disposed on the second insulating layer 151B and covering the second wiring layer 152B, a third wiring layer 152C disposed on the third insulating layer 151C, and a third via 153C penetrating the third wiring layer 152C and the third insulating layer 151C and electrically connecting the second wiring layer 152B and the third wiring layer 152C. However, the number of layers of the fourth redistribution structure 150 may be less or more than that shown in the drawings.

An insulating material may be used as the material for the insulating layer 151. For example, the insulating layer 151 may include a thermoplastic resin such as polyimide (PI), a thermosetting resin such as epoxy, polybenzoxazole (PBO), or benzocyclobutene (BCB), or a resin in which these resins are mixed with an inorganic filler (e.g., the Ajinomoto build-up film (ABF)). In some embodiments, the insulating layer 151 may include the photo-imageable dielectric (PID) that is capable of being patterned by a photolithographic process. For example, the insulating layer 151 may include photosensitive polyimide (PSPI). When the insulating layer 151 includes the PID, a fine pitch may be implemented through formation of a photo via. When the insulating layer 151 is multi-layered, the material of each insulating layer 151 may be the same or different. When the insulating layer 151 is multi-layered, the insulating layers 151 may have boundaries with each other, may have unclear boundaries, or may be integrated and have no boundaries.

Each of the wiring layers 152 may be disposed on a corresponding one (or corresponding pair) of the insulating layers 151. The wiring layer 152 may include a wiring pattern (e.g., a signal pattern, a power pattern, a ground pattern, etc.), a via pad for connection to the via 153, a connection pad for electrical connection to other components (e.g., which may be included in an uppermost wiring layer 152C), etc. A conductive material may be used as the material for the wiring layer 152. For example, the wiring layer 152 may include a metal such as aluminum (Al), copper (Cu), titanium (Ti), tungsten (W), gold (Au), platinum (Pt), silver (Ag), tin (Sn), chromium (Cr), palladium (Pd), or an alloy of two or more of these.

Each via 153 penetrates at least one of the insulating layers 151 and may physically and/or electrically connect the wiring layers 152 disposed in different layers. Some of the vias 153, such as the lowermost via 153A, may electrically connect the wiring layer 152 to the conductive post 160. The via 153 may have various shapes, such as a tapered shape with a width that narrows from one side to the other side, or a cylindrical shape. A conductive material may be used as the material for the via 153. For example, the via 153 may include a metal such as aluminum (Al), copper (Cu), titanium (Ti), tungsten (W), gold (Au), platinum (Pt), silver (Ag), tin (Sn), chromium (Cr), palladium (Pd), or an alloy of two or more of these. The via 153 may be formed by completely filling a via hole with a conductive material, or by conformally forming a conductive material along the wall and the bottom surface of the via hole. The via 153 may be formed integrally with the wiring layer 112 disposed on the upper side thereof. For example, the via 153 and the wiring layer 152 may be formed by forming a via hole penetrating the insulating layer 151 and filling the via hole with a conductive material to fill the via hole and extend over the insulating layer 151. The via 153 and the wiring layer 152 may include the first conductive layer functioning as a seed layer and the second conductive layer disposed on the first conductive layer. The first conductive layer may extend along the surface of the insulating layer 151, the wall, and the bottom surface of the via hole.

The conductive post 160 may be embedded in the third encapsulant 140 and electrically connect the third redistribution structure 250 and the fourth redistribution structure 150. The conductive post 160 may be in contact with the third redistribution structure 250 and the fourth redistribution structure 150. The upper surface of the conductive post 160 may be exposed at (or may be exposed beyond, or may terminate flush with) the upper surface of the third encapsulant 140. The upper surface of the conductive post 160 may be coplanar with the upper surface of the third encapsulant 140. In some embodiments, the conductive post 160 may physically and/or electrically connect the wiring layer 252 of the third redistribution structure 250 to the lowermost via 153A of the fourth redistribution structure 150. In some embodiments, the conductive post 160 may physically and/or electrically connect the wiring layer 252 of the third redistribution structure 250 to a wiring layer (not shown) disposed on the third encapsulant 140 and embedded in the lowermost insulating layer 151A of the fourth redistribution structure 150. A conductive material may be used as the material for the conductive post 160. For example, the conductive post 160 may include a metal such as aluminum (Al), copper (Cu), titanium (Ti), tungsten (W), gold (Au), platinum (Pt), silver (Ag), tin (Sn), chromium (Cr), palladium (Pd), or an alloy of two or more of these. The conductive post 160 may include the first conductive layer functioning as a seed layer and the second conductive layer disposed on the first conductive layer. The conductive post 160 may be disposed to surround the second semiconductor chip 130, but it is not limited thereto. The number, spacing, etc. of the conductive posts 160 are not particularly limited.

The aspect ratio of the conductive post 160 may be 10 or less. For example, the aspect ratio of the conductive post 160 may be less than 10, less than or equal to 9, less than or equal to 8, less than or equal to 7, less than or equal to 6, less than or equal to 5, or less than 5. For example, the aspect ratio of a conductive post may be the post's vertical height (from the bottom surface to the top surface) divided by a horizontal dimension measured at a reference plane (e.g., at a mid-height). For example, the horizontal dimension may be the minimum width (or an equivalent diameter). In the present disclosure, by forming the conductive post 160 on the second redistribution structure 210, the present disclosure may provide a conductive post 160 having a low aspect ratio of 10 or less. Therefore, it is possible to prevent or reduce defects that may occur when forming a conductive post having a high aspect ratio (e.g., defects due to photoresist residue, unintended electrical disconnection (e.g., conductive post open defects due to reduced height uniformity of the conductive post), misalignment of the post (e.g., via alignment defects), etc.). It is also possible to prevent or reduce process steps required for forming a two-stage conductive post (e.g., a combination of first post and a second post stacked on the first post) and other defects (e.g., bubbles, cracks, swelling defects of a photoresist pattern, etc.).

A semiconductor package 10A (that is manufactured by packaging the sub-package 200 including the first semiconductor chip 230 and the second semiconductor chip 130 together) may be manufactured using a wafer level packaging (WLP) process. After being separated into individual semiconductor packages, each side surface of the first redistribution structure 110, the second encapsulant 120, the third encapsulant 140, and the fourth redistribution structure 150 of the semiconductor package 10A may be coplanar. For example, the first redistribution structure 110, the second encapsulant 120, the third encapsulant 140, and the fourth redistribution structure 150 are singulated in a single operation. Accordingly, the sidewalls of the first redistribution structure 110, the second encapsulant 120, the third encapsulant 140, and the fourth redistribution structure 150 may be flush with one another and terminate on substantially the same cut plane. In a plan view, the sidewalls of the first redistribution structure 110, the second encapsulant 120, the third encapsulant 140, and the fourth redistribution structure 150 may be spaced apart from the frame by a horizontal distance HD by the second encapsulant 120.

In contrast to the disclosed embodiments, when implementing logic chips as a single chip, there is a concern that product productivity and yield may decrease due to differences in process nodes and pitches of each logic unit. In addition, when connecting the lower and upper redistribution structures of the semiconductor package with the conductive post, the application of the conductive post having a high aspect ratio (e.g., greater than 10) is typically required due to a decrease in the diameter and pitch of the conductive posts as the number of input/output (I/O) terminals increases. For conductive posts with high aspect ratios, defects due to photoresist residue, conductive post open defects due to reduced height uniformity of the conductive post, and via alignment defects may occur. When forming a two-stage conductive post as a replacement for the conductive post with a high aspect ratio, not only is an additional process required, but bubbles, cracks, and swelling defects in the second photoresist may occur.

According to the present disclosure, by forming the second semiconductor chip 130 of the tip end node separately or independently from the first semiconductor chip 230, the product yield may be improved and efficient characteristics of each semiconductor chip may be implemented. For example, this configuration facilitates independent optimization of each chip's characteristics. In addition, as described below, by manufacturing the sub-package 200 including the first semiconductor chip 230 using a panel level packaging (PLP) process, product productivity may be improved as compared to a wafer level packaging process. Further, by packaging the first semiconductor chip 230 first to form the sub-package 200 and only packaging the good-quality sub-package 200 with the high-cost second semiconductor chip 130 second, the loss of the second semiconductor chip 130 may be minimized or reduced. For example, each chip type may be fabricated in multiples, and only known-good dice (i.e., dice that have passed pre-assembly screening) may be assembled to form final package products. This approach, unlike a conventional package, reduces scrapping of comparatively expensive advanced-node dice among the two kinds of chips. In addition, by introducing the sub-package 200 between the first redistribution structure 110 and the fourth redistribution structure 150 to form the conductive post 160 on the third redistribution structure 250, the conductive post 160 having a low aspect ratio of 10 or less may be provided. Therefore, it is possible to prevent or reduce problems that may occur when forming the conductive post with a high aspect ratio.

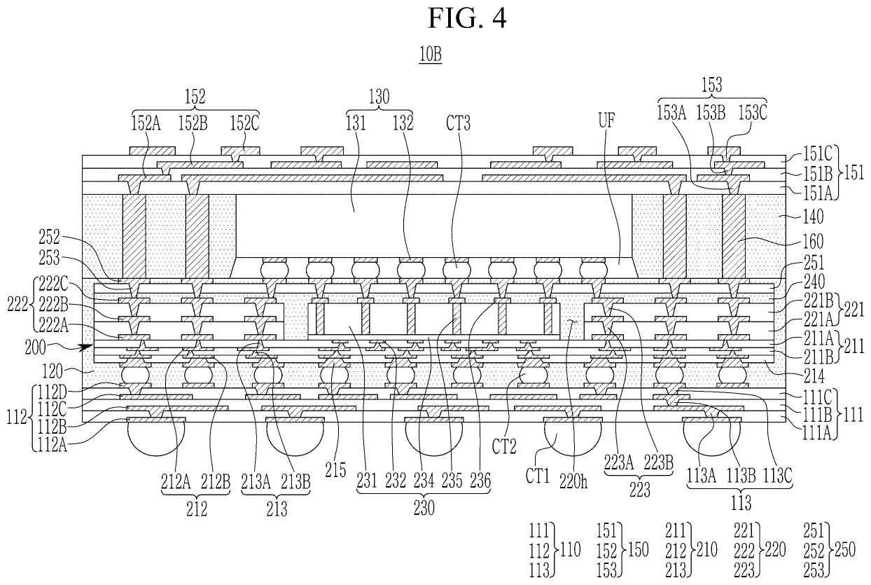

FIG. 4 is a cross-sectional view of the semiconductor package according to another embodiment.

In a semiconductor package 10B, the first semiconductor chip 230 may further include a second connection pad 236 facing the third redistribution structure 250 and electrically connected to the third redistribution structure, and a through via 235 electrically connecting the first connection pad 232 and the second connection pad 236. By forming the through via 235 and the second connection pad 236 connected thereto in the first semiconductor chip 230, the first semiconductor chip 230 capable of responding to an increase in the number of input/output terminals may be provided.

The through via 235 penetrates between the upper and lower surfaces of the semiconductor substrate 231 and may electrically connect the wiring structure 234 and the second connection pad 236. The through via 235 may have a cylindrical shape, but it is not limited thereto. A conductive material may be used as the material for the through via 235. For example, the through via 235 may include a metal or an alloy of metals such as copper (Cu), aluminum (Al), tungsten (W), titanium (Ti), or tantalum (Ta). An insulating film may be disposed between the through via 235 and the semiconductor substrate 231 for electrical insulation therebetween. As the material of the insulating film, insulating materials such as silicon oxide, silicon nitride, and polyimide may be used. Additionally, a barrier film may be further disposed between the through via 235 and the insulating film to prevent or reduce diffusion of the material (e.g., copper (Cu)) of the through via 235. Materials that may be used for the barrier film include tungsten (W), cobalt (Co), titanium (Ti), tantalum (Ta), ruthenium (Ru), etc. The through via 235 may be formed using a via-first, via-middle or via-last method, and the through via 235 may further penetrate at least a portion of the wiring structure 234 depending on the formation method.

The second connection pad 236 may be disposed on the upper surface of the semiconductor substrate 231 and electrically connected to the through via (235). Additionally, the second connection pad 236 may be electrically connected to the wiring layer 252 through the via 253 of the third redistribution structure 250. A conductive material may be used as the material for the second connection pad 236. For example, the second connection pad 236 may include a metal such as aluminum (Al), copper (Cu), titanium (Ti), tungsten (W), gold (Au), platinum (Pt), silver (Ag), tin (Sn), chromium (Cr), palladium (Pd), or an alloy of two or more of these.

In addition, to the extent not inconsistent with the present disclosure, the description of other components may likewise be applied to the contents described in the description of the semiconductor package 10A according to an embodiment of the present disclosure.

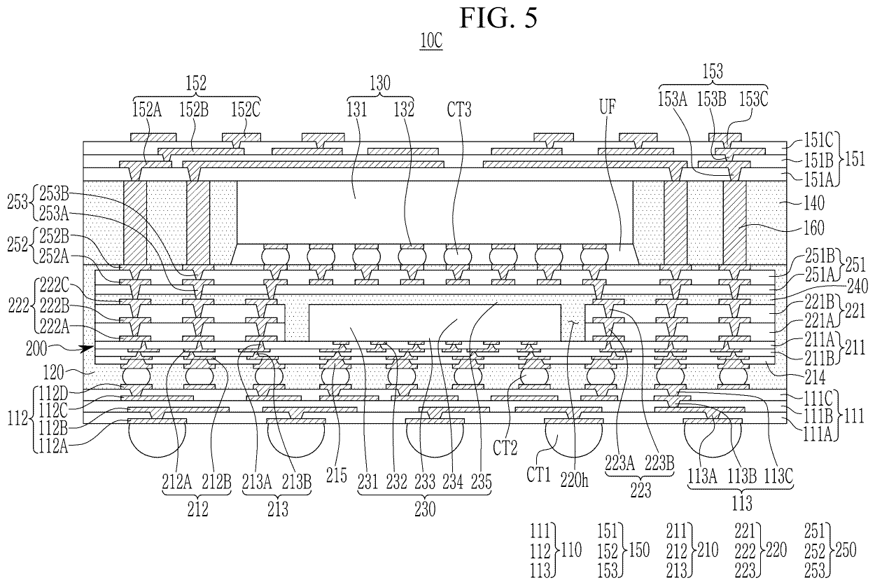

FIG. 5 is a cross-sectional view of the semiconductor package according to another embodiment.

In a semiconductor package 10C, the third redistribution structure 250 may include a plurality of insulating layers 251 and a plurality of wiring layers 252. For example, the third redistribution structure 250 may include a first insulating layer 251A, a first wiring layer 252A disposed on the first insulating layer 251A, the first via 223A penetrating the first insulating layer 251A and extending into the first encapsulant 240 to electrically connect the first wiring layer 252A and the frame 220, a second insulating layer 251B disposed on the first insulating layer 251A to cover the first wiring layer 252A, a second wiring layer 252B disposed on the second insulating layer 251B, and a second via 253B penetrating the second insulating layer 251B to electrically connect the second wiring layer 252B and a third wiring layer 252C. Among the plurality of wiring layers 252, the wiring layer exposed at the upper surface of the second encapsulant 120 may be the uppermost wiring layer 252B adjacent to the second semiconductor chip 130. By configuring the third redistribution structure 250 into a plurality of layers, the freedom of wiring design may be improved.

In addition, to the extent not inconsistent with the present disclosure, the description of other components may likewise be applied to the contents described in the description of the semiconductor package 10A according to an embodiment of the present disclosure.

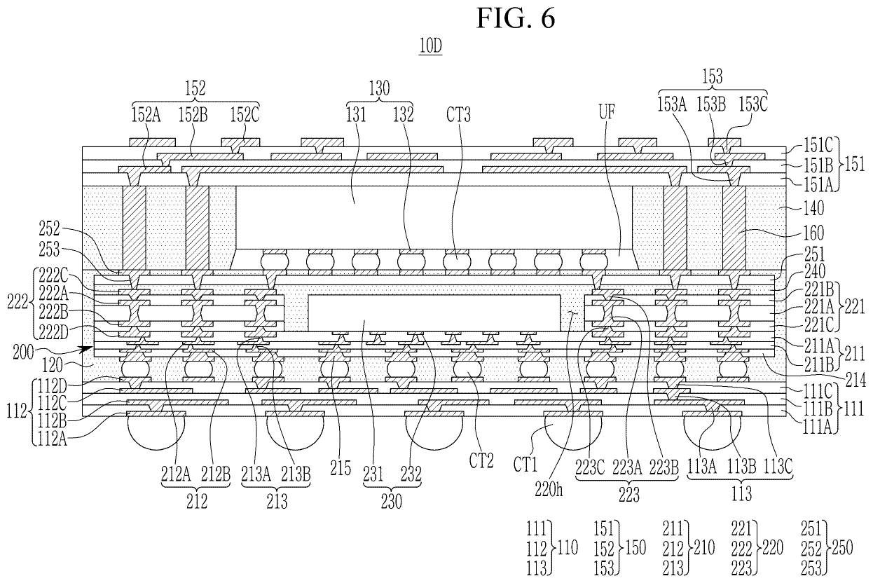

FIG. 6 is a cross-sectional view of the semiconductor package according to another embodiment.

The frame 220 of a semiconductor package 10D may include the first insulating layer 221A, the first wiring layer 222A disposed on the upper surface of the first insulating layer 221A, the second wiring layer 222B disposed on the lower surface of the first insulating layer 221A, the first via 223A penetrating the first insulating layer 221A and electrically connecting the first wiring layer 222A and the second wiring layer 222B, the second insulating layer 221B disposed on the upper surface of the first insulating layer 221A and covering the first wiring layer 222A, the third wiring layer 222C disposed on the second insulating layer 221B, the second via 223B penetrating the second insulating layer 221B and electrically connecting the first wiring layer 222A and the third wiring layer 222C, a third insulating layer 221C disposed on the lower surface of the insulating layer 221A and covering the second wiring layer 222B, a fourth wiring layer 222D disposed on the third insulating layer 221C, and a third via 223C penetrating the third insulating layer 221C and electrically connecting the second wiring layer 222B and the fourth wiring layer 222D. The first insulating layer 221A may function as a core insulating layer and may be thicker than the second insulating layer 221B and the third insulating layer 221C, but it is not limited thereto. The first insulating layer 221A may be formed of a material having superior rigidity to the second insulating layer 221B and the third insulating layer 221C, but it is not limited thereto. For example, Young's modulus of the material for forming the first insulating layer 221A may be greater than that of the material for forming the second insulating layer 221B and/or the material for forming the third insulating layer 221C.

In addition, to the extent not inconsistent with the present disclosure, the description of other components may likewise be applied to the contents described in the description of the semiconductor package 10A according to an embodiment of the present disclosure.

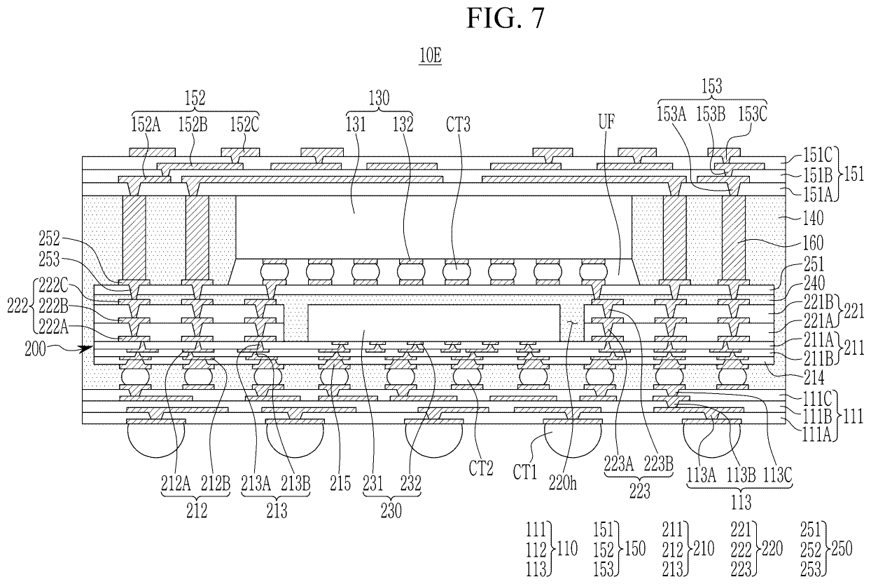

FIG. 7 is a cross-sectional view of the semiconductor package according to another embodiment.

A semiconductor package 10E does not include the second encapsulant 120, and the third encapsulant 140 may be integrally formed to continuously cover the sub-package 200, the second semiconductor chip 130, and the conductive post 160. The semiconductor package 10E as shown in FIG. 7 may be manufactured by arranging the second semiconductor chip 130 and the conductive post 160 on the sub-package 200 and then molding them integrally by using the integrally formed third encapsulant 140.

In addition, to the extent not inconsistent with the present disclosure, the description of other components may likewise be applied to the contents described in the description of the semiconductor package 10A according to an embodiment of the present disclosure.

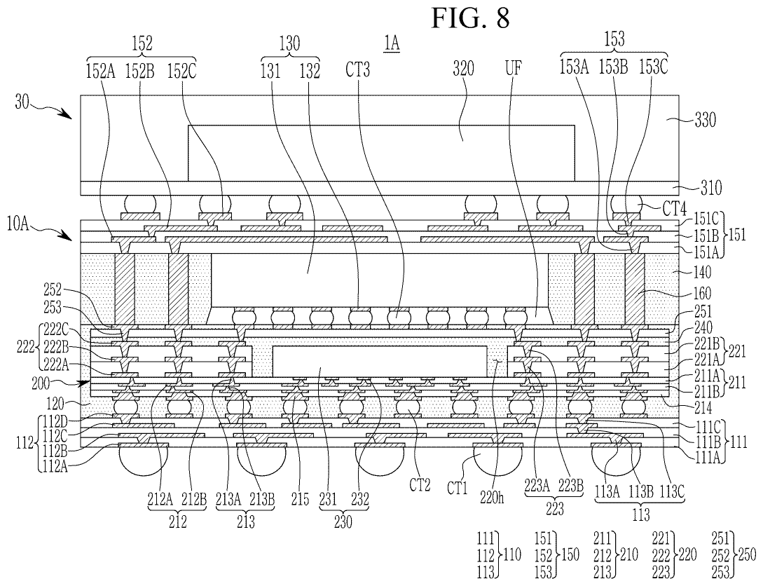

FIG. 8 is a cross-sectional view of a package-on-package (or a package-on-package device) including the semiconductor package illustrated in FIG. 1.

A package-on-package 1A according to an embodiment includes the first semiconductor package 10A and a second semiconductor package 30 disposed on the first semiconductor package 10A.

The first semiconductor package 10A is illustrated as the semiconductor package illustrated in FIG. 1, but it may be replaced with any one of the semiconductor packages according to other embodiments of the present disclosure—for example, the semiconductor packages 10B, 10C, 10D, and 10E illustrated in FIGS. 4 to 7.

The second semiconductor package 30 may include an interconnect structure 310, a third semiconductor chip 320, and a fourth encapsulant 330. However, an unpackaged third semiconductor chip 320 may be mounted on the first semiconductor package 10A.

The interconnect structure 310 may electrically connect the third semiconductor chip 320 and the first semiconductor package 10A. The interconnect structure 310 may be, for example, a package substrate or a redistribution structure. In some embodiments, the third semiconductor chip 320 may be flip-chip bonded or wire bonded to the interconnect structure 310. For example, the third semiconductor chip 320 may be formed by a flip-chip bonding process or by a wire bonding process onto the interconnect structure 310. In some embodiments, the third semiconductor chip 320 may be disposed directly on the interconnect structure 310 in a chip-first manner. For example, the third semiconductor chip 320 may be placed and/or molded prior to formation of the interconnect structure 310.

The third semiconductor chip 320 may include or be a memory chip. The memory chip may include a memory circuit, and may include, for example, at least one of a high-bandwidth memory (HBM), a dynamic random access memory (DRAM), a static random access memory (SRAM), a flash memory, a read-only memory (ROM), and a magnetic random access memory (MRAM).

The fourth encapsulant 330 may cover at least a portion of the third semiconductor chip 320. An insulating material may be used as the material for the fourth encapsulant 330. For example, the fourth encapsulant 330 may include an epoxy molding compound (EMC). Alternatively, the fourth encapsulant 330 may include a thermoplastic resin such as polyimide (PI), a thermosetting resin such as epoxy, or a resin in which these resins are mixed with an inorganic filler such as SiO₂ (e.g., the Ajinomoto build-up film (ABF)). Alternatively, the fourth encapsulant 330 may include a photo-imageable dielectric (PID), such as photosensitive polyimide (PSPI).

A fourth connection terminal CT4 may be disposed between the second semiconductor package 30 and the first semiconductor package 10A for electrical connection therebetween. The fourth connection terminals CT4 may provide (or be configured as) a ball grid array, a land grid array, or a pin grid array. A conductive material may be used as the material for the fourth connection terminal CT4. For example, the fourth connection terminal CT4 may be a solder ball including solder formed of an Sn—Ag alloy, an Sn—Ag—Cu alloy, or the like. Alternatively, the fourth connection terminal CT4 may include a metal or an alloy of metals. There are no particular restrictions on the size, number, spacing, arrangement, etc. of the fourth connection terminal CT4.

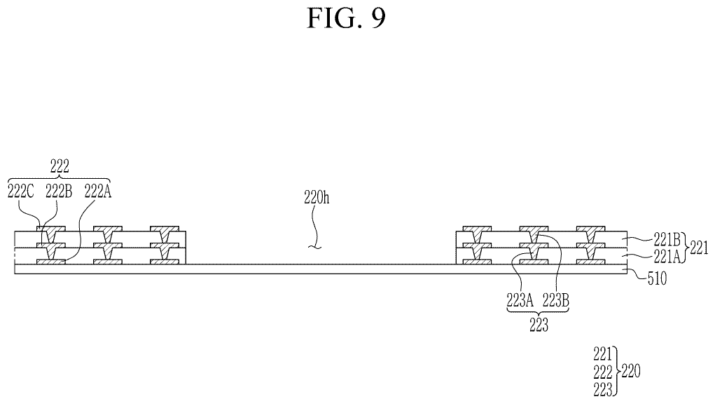

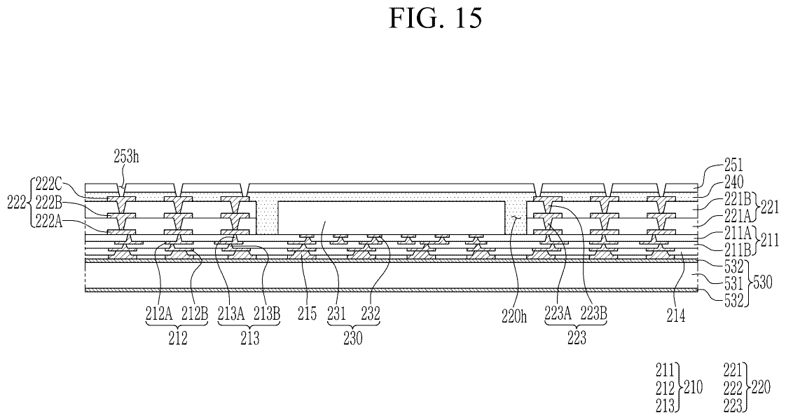

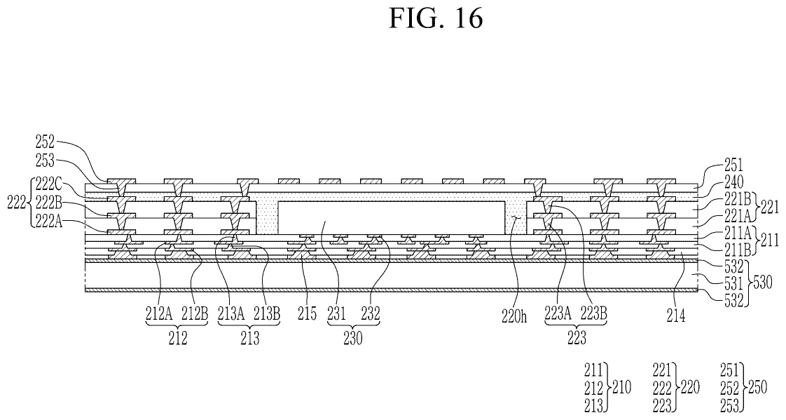

FIGS. 9 to 29 are cross-sectional views sequentially showing a method for manufacturing the semiconductor package illustrated in FIG. 1.

A method for manufacturing the semiconductor package 10A may include a step (or process) of packaging the first semiconductor chip 230 to form the sub-package 200 and a step (or process) of packaging the sub-package 200 and the second semiconductor chip 130 together. A fan-out panel level packaging (Fo-PLP) process may be applied in the steps of forming the sub-package 200, and a fan-out wafer level packaging (Fo-WLP) process may be applied in the steps of packaging the sub-package 200 and the second semiconductor chip 130 together. For example, the semiconductor package 10A may be manufactured by cutting a reconstituted panel (including the sub-packages 200 formed on the panel), by using a process that packages first semiconductor chips 230 at panel level (e.g., the first semiconductor chips 230 may be manufactured collectively in form of a panel). The process may include separating the reconstituted panel into individual sub-packages 200, packaging the sub-packages 200 at wafer level (e.g., the sub-packages 200 may be manufactured collectively in form of a wafer), and then cutting the reconstituted panel.

Hereinafter, an exemplary method for manufacturing the semiconductor package illustrated in FIG. 1 will be described step by step with reference to the drawings. The drawings illustrate only some of the regions included in one semiconductor package 10A of components packaged at panel level or wafer level. For example, although multiple packages may be formed concurrently at the wafer or panel level, the drawings illustrate only one example package 10A, for clarity of explanation.

First, referring to FIG. 9, the frame 220 having the through hole 220h is prepared. The through hole 220h may be formed by laser processing, mechanical processing, etc. A first adhesive 510 may be attached to the lower surface of the frame 220. The first adhesive 510 may be exposed at the bottom surface of the through hole 220h. The first adhesive 510 may be, for example, a polyimide (PI) tape.

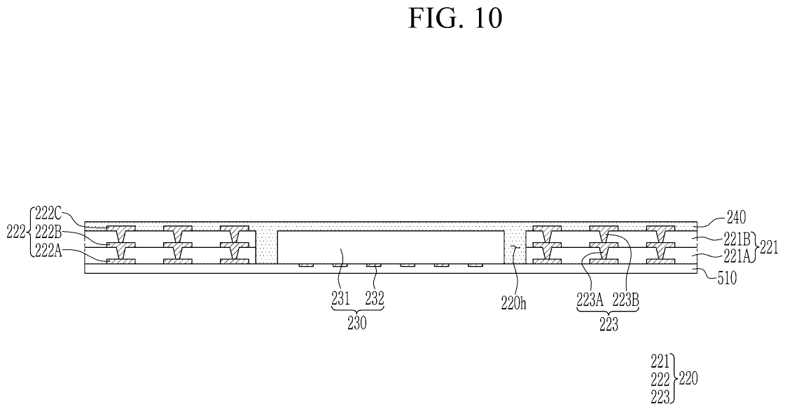

Next, referring to FIG. 10, the first semiconductor chip 230 is disposed within the through hole 220h, and the first semiconductor chip 230 is molded with the first encapsulant 240. The first semiconductor chip 230 disposed within the through hole 220h may be attached and secured to the first adhesive 510 exposed at the bottom surface of the through hole 220h. The process of molding the first semiconductor chip 230 with the first encapsulant 240 may be performed by, for example, compression molding or transfer molding.

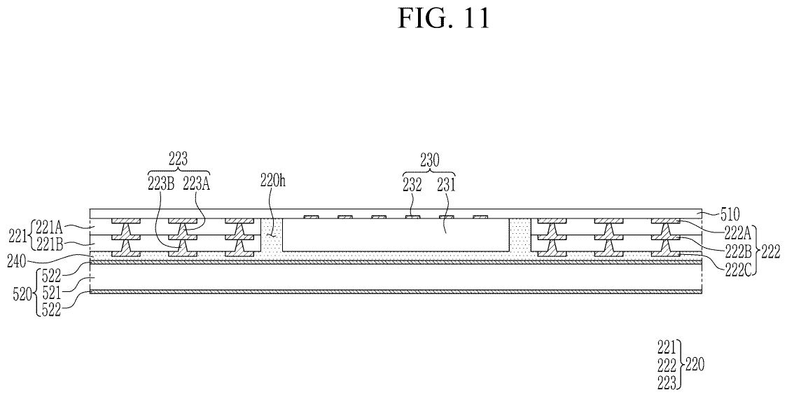

Next, referring to FIG. 11, a first carrier substrate 520 is attached to the first encapsulant 240. The first carrier substrate 520 may have, for example, a dual copper foil (DCF) structure including a base substrate layer 521 and copper layers 522 disposed on both surfaces of the base substrate layer 521. If necessary, the first carrier substrate 520 may be attached to the first encapsulant 240 using an adhesive.

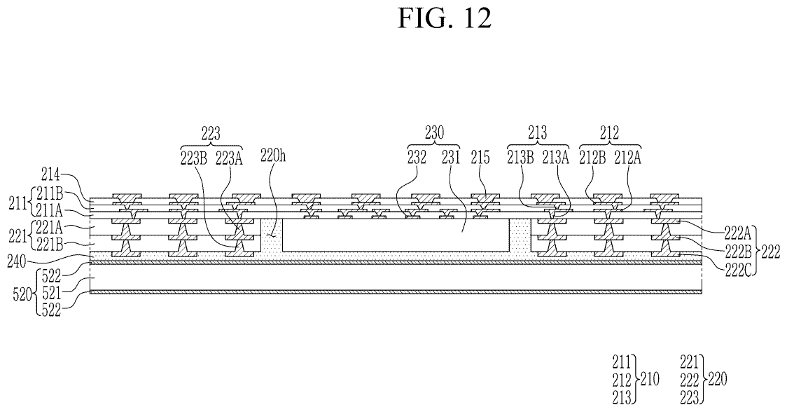

Next, referring to FIG. 12, the second redistribution structure 210 is formed on the first semiconductor chip 230 and the frame 220, and the passivation layer 214 and the under bump metal layer 215 are formed on the second redistribution structure 210. The second redistribution structure 210 may be manufactured by sequentially forming the insulating layer 211, the via 213 penetrating the insulating layer 211, and the wiring layer 212 disposed on the insulating layer 211, and repeating the sequence as needed. The passivation layer 214 may be formed on the second insulating layer 211B of the second redistribution structure 210. An opening exposing the second wiring layer 212B may be formed in the passivation layer 214. The under bump metal layer 215 may be formed to fill the opening in the passivation layer 214 and extend onto the passivation layer 214.

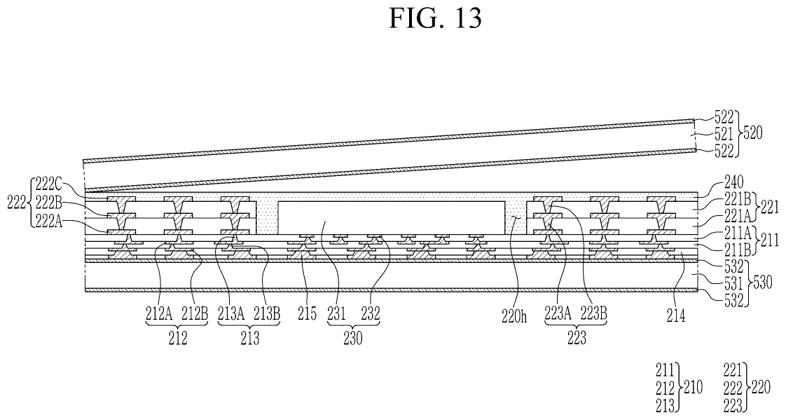

Next, referring to FIG. 13, the first carrier substrate 520 is detached, and the second carrier substrate 530 is attached to the under bump metal layer 215. The second carrier substrate 530 may have a dual copper foil (DCF) structure that includes a base substrate layer 531 and copper layers 532 disposed on both surfaces of the base substrate layer 531, similar to the first carrier substrate 520. If necessary, the second carrier substrate 530 may be attached to the under bump metal layer 215 using an adhesive.

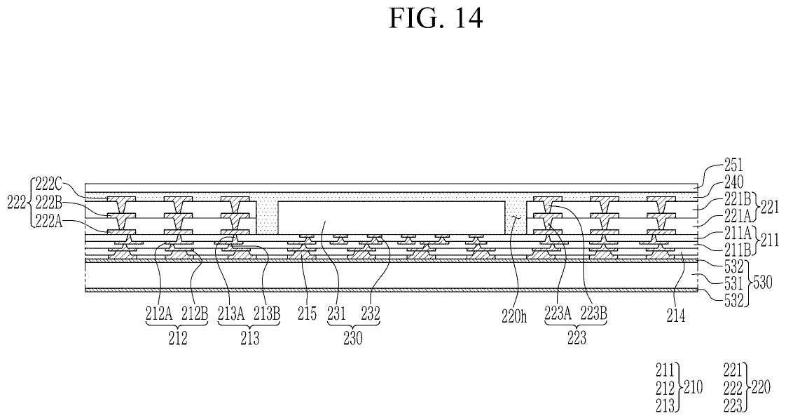

Next, referring to FIGS. 14 to 16, the third redistribution structure 250 is formed on the first encapsulant 240. The third redistribution structure 250 may be manufactured by forming the insulating layer 251 on the first encapsulant 240, processing the insulating layer 251 and the first encapsulant 240 to form a via hole 253h that exposes the wiring layer 222 of the frame 220, and then forming the via 253 that fills the via hole 253h and the wiring layer 252 that is disposed on the insulating layer 251. The via hole 253h may be formed, for example, by laser processing on the insulating layer 251 and the first encapsulant 240.

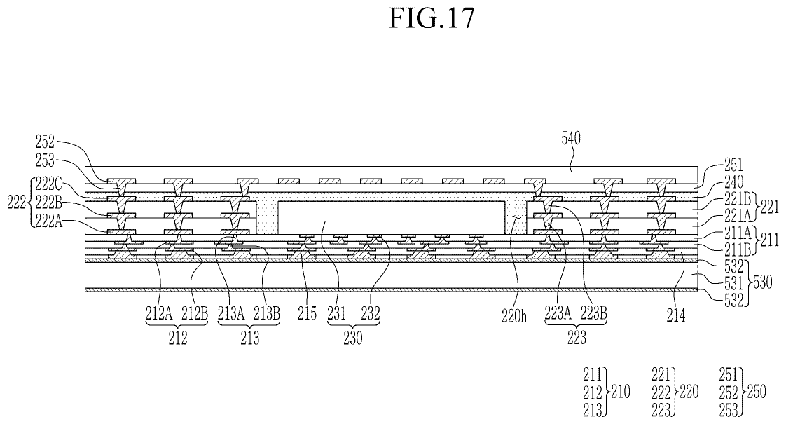

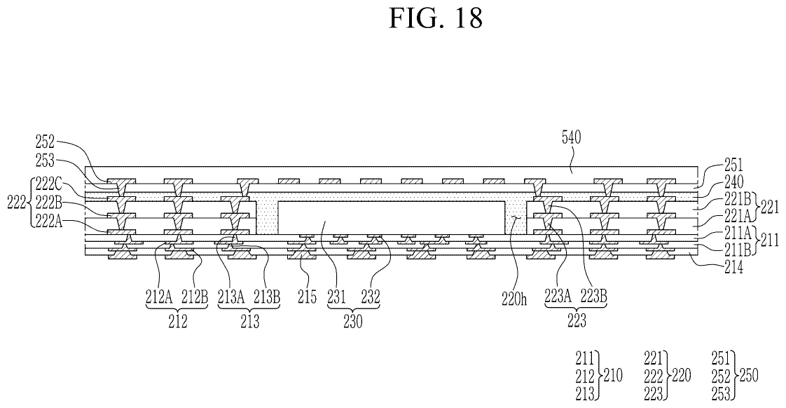

Next, referring to FIGS. 17 and 18, a second adhesive 540 is attached to the third redistribution structure 250, and the second carrier substrate 530 is detached from the under bump metal layer 215. The second adhesive 540 may be, for example, a polyimide (PI) tape.

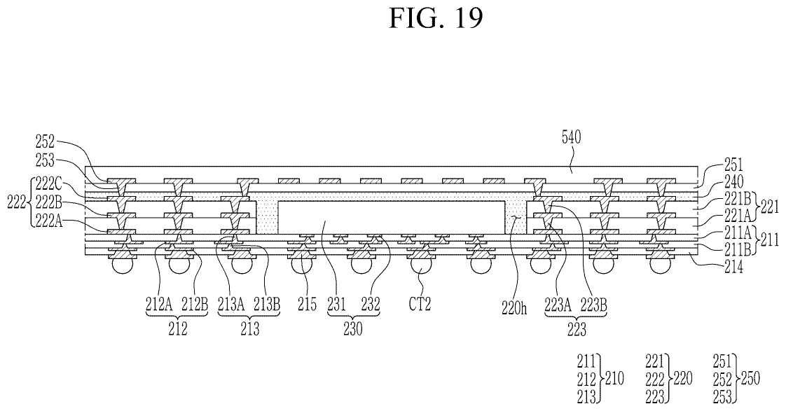

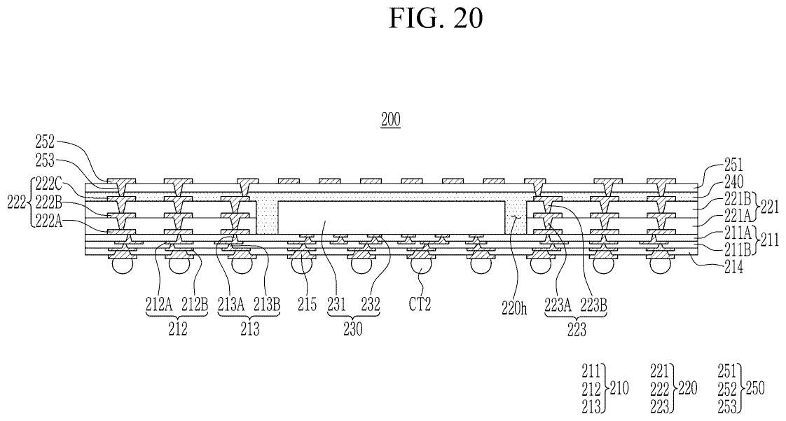

Next, referring to FIGS. 19 and 20, the second connection terminal CT2 is formed on the under bump metal layer 215, and the packaged reconfigured panel is cut at panel level to separate it into individual sub-packages 200. Additionally, the second adhesive 540 is detached from the sub-package 200.

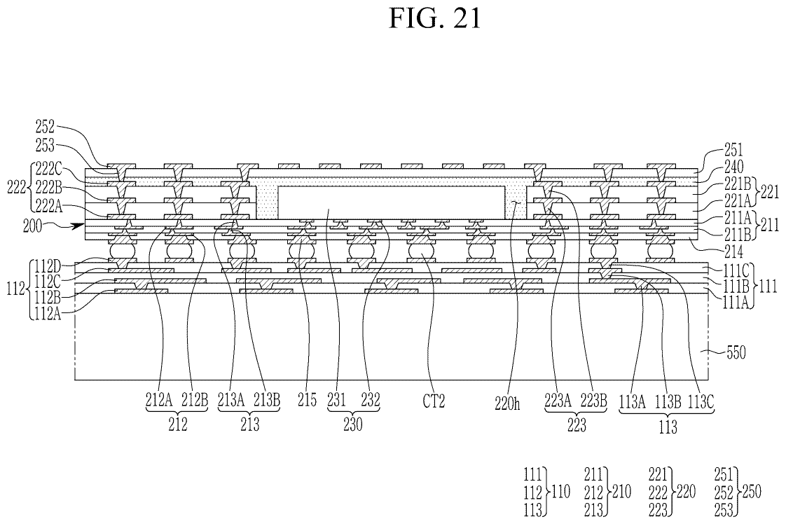

Next, referring to FIG. 21, the sub-package 200 is disposed on the first redistribution structure 110, which is disposed on a third carrier substrate 550. The third carrier substrate 550 may be, for example, a glass carrier substrate at wafer-level (e.g., in form of a wafer). The first redistribution structure 110 may be formed on the third carrier substrate 550. The first redistribution structure 110 may be manufactured, for example, by sequentially forming the insulating layer 111, the via 113 penetrating the insulating layer 111, and the wiring layer 112 disposed on the insulating layer 111 on the third carrier substrate 550, and repeating the sequence as needed. The sub-package 200 may be mounted on the first redistribution structure 110 using the second connection terminal CT2.

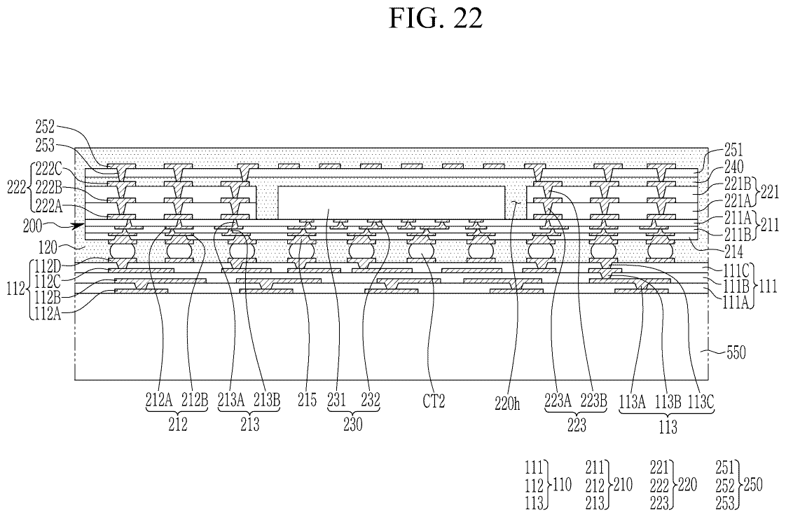

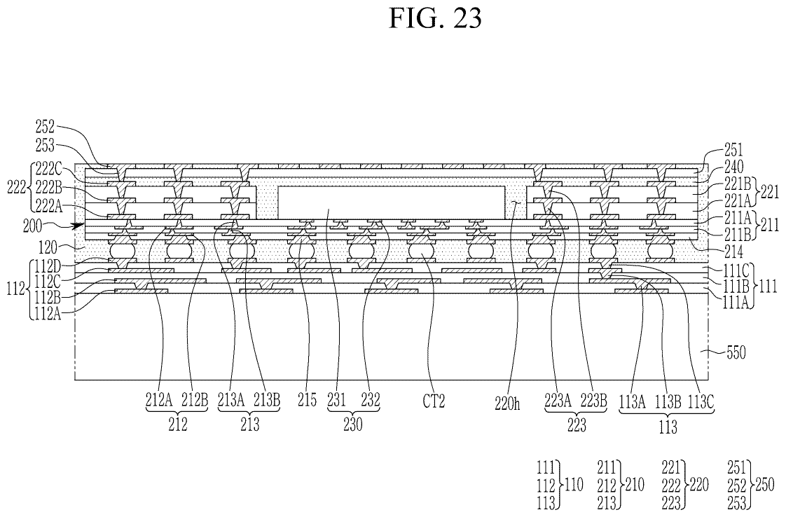

Next, referring to FIGS. 22 and 23, the sub-package 200 is molded with the second encapsulant 120, and the upper surface of the second encapsulant 120 is ground (or removed) to expose the wiring layer 252 of the third redistribution structure 250. The process of molding the sub-package 200 with the second encapsulant 120 may be performed, for example, by compression molding or transfer molding. By grinding the upper surface of the second encapsulant 120, the upper surfaces of the sub-packages 200 molded together at the wafer level may be planarized. Therefore, in a subsequent process, a seed layer (e.g., the exposed wiring layer 252) of the conductive post 160 may be uniformly formed on the sub-package 200.

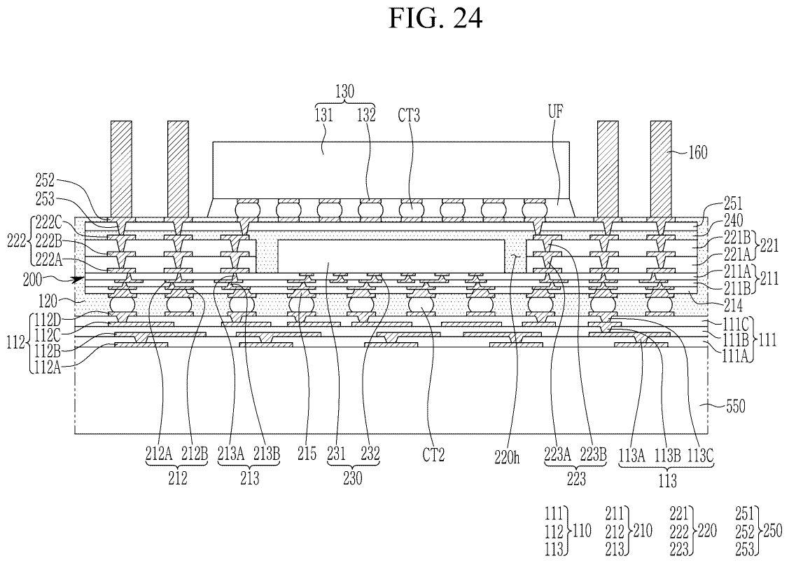

Next, referring to FIG. 24, the conductive post 160 is formed on the third redistribution structure 250, and the second semiconductor chip 130 is disposed. In some embodiments, the conductive post 160 may be manufactured by forming an additional seed layer on the wiring layer 252 and forming a plating layer on the seed layer. The second semiconductor chip 130 may be mounted on the wiring layer 252 using the third connection terminal CT3. If necessary, an additional process of covering the third connection terminal CT3 with the underfill material UF may be performed.

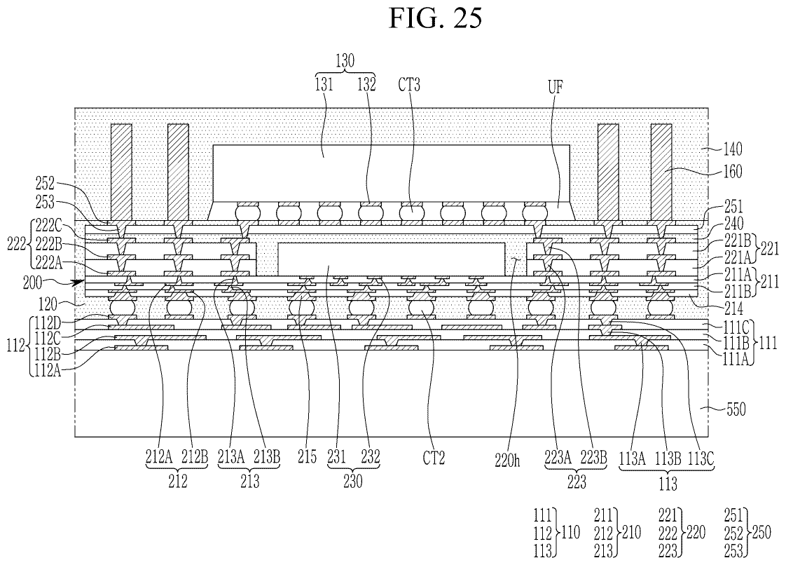

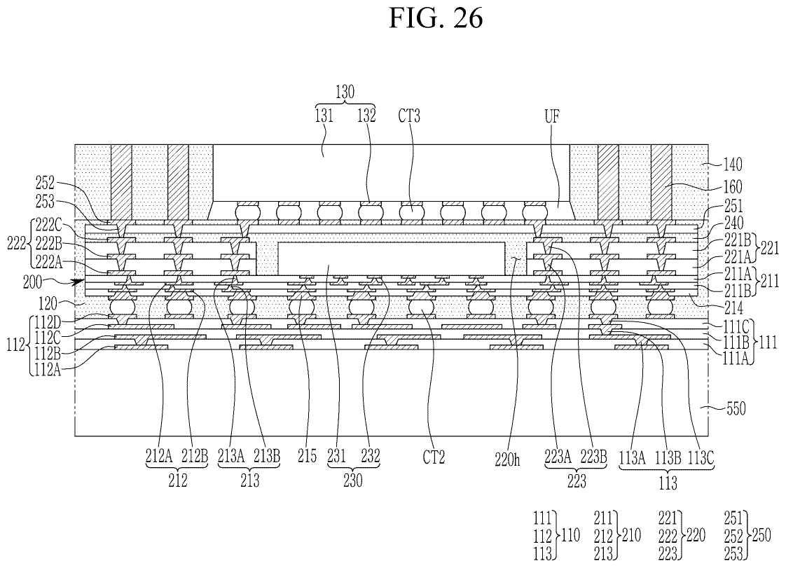

Next, referring to FIGS. 25 and 26, the conductive post 160 and the second semiconductor chip 130 are molded with the third encapsulant 140, and the upper surface of the third encapsulant 140 is ground to expose the upper surface of the conductive post 160. The process of molding the conductive post 160 and the second semiconductor chip 130 with the third encapsulant 140 may be performed by, for example, compression molding or transfer molding. In the process of grinding the upper surface of the third encapsulant 140, the upper surface of the second semiconductor chip 130 may be exposed along with it, but it is not limited thereto.

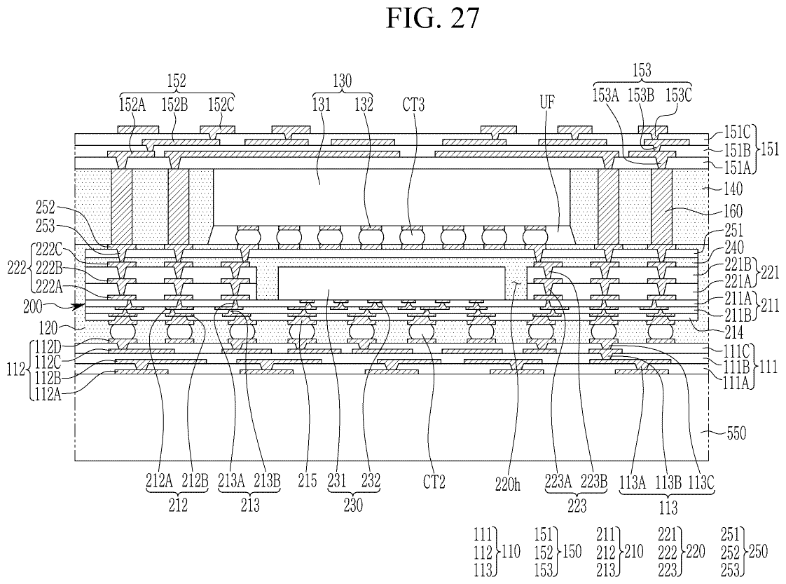

Next, referring to FIG. 27, the fourth redistribution structure 150 is formed on the third encapsulant 140. The fourth redistribution structure 150 may be manufactured by sequentially forming the insulating layer 151, the via 153 penetrating the insulating layer 151, and the wiring layer 152 disposed on the insulating layer 151, and repeating the sequence as needed.

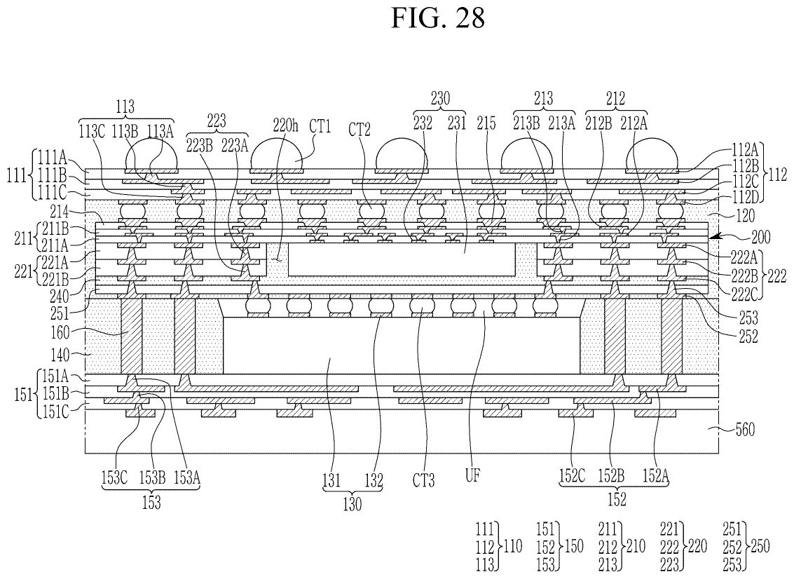

Next, referring to FIG. 28, a third adhesive 560 is attached to the fourth redistribution structure 150, the third carrier substrate 550 is detached from the first redistribution structure 110, and then the first connection terminal CT1 is formed on the first redistribution structure 110. A known tape (e.g., as described above) may be used as the third adhesive 560.

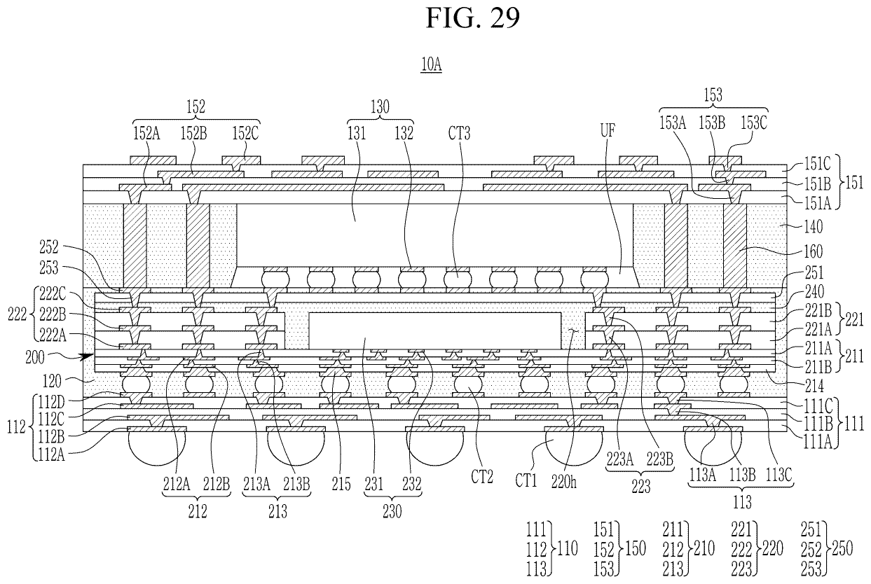

Next, referring to FIG. 29, the semiconductor packages at wafer level is cut and separated into individual semiconductor packages 10A. Additionally, the third adhesive 560 is detached from the individual semiconductor packages 10A.

While the embodiments of the present disclosure have been described in detail, it is to be understood that the invention is not limited to the disclosed embodiments, and various modifications and equivalents thereof will be apparent to those skilled in the art.

In addition, the embodiments of the present disclosure are not mutually exclusive and may be implemented in combination with each other unless they are particularly contradictory. Accordingly, combinations of the embodiments of the present disclosure should also be considered as being included in the present disclosed embodiments.

What is claimed is:

1. A semiconductor package, comprising:
a first interconnection layer;
a sub-package disposed on the first interconnection layer, the sub-package comprising:
a second interconnection layer,
an apertured interconnection layer disposed on the second interconnection layer and having a through hole,
a first semiconductor chip disposed within the through hole,
a first encapsulant filling a portion of the through hole and covering a portion of the first semiconductor chip, and
a third interconnection layer disposed on the first encapsulant;
a second encapsulant covering a portion of the sub-package;
a second semiconductor chip disposed on the second encapsulant;
a third encapsulant covering a portion of the second semiconductor chip;
a fourth interconnection layer disposed on the third encapsulant; and
a conductive post embedded in the third encapsulant and electrically connecting the sub-package and the fourth interconnection layer.

2. The semiconductor package of claim 1, wherein
the first semiconductor chip comprises a first connection pad facing the second interconnection layer and electrically connected to the second interconnection layer.

3. The semiconductor package of claim 2, wherein
the first semiconductor chip further comprises:
a second connection pad facing the third interconnection layer and electrically connected to the third interconnection layer, and
a through via electrically connecting the first connection pad and the second connection pad.

4. The semiconductor package of claim 1, wherein
the third interconnection layer comprises a wiring layer exposed at an upper surface of the second encapsulant.

5. The semiconductor package of claim 4, wherein
an upper surface of the wiring layer and the upper surface of the second encapsulant are coplanar.

6. The semiconductor package of claim 1, wherein
the second encapsulant covers a side surface of the sub-package.

7. The semiconductor package of claim 6, wherein
side surfaces of the first interconnection layer, the second encapsulant, the third encapsulant, and the fourth interconnection layer are coplanar.

8. The semiconductor package of claim 1, wherein the apertured interconnection layer comprises:
a first wiring layer,
a first insulating layer covering the first wiring layer,
a second wiring layer disposed on the first insulating layer and electrically connected to the first wiring layer,
a second insulating layer disposed on the first insulating layer and covering the second wiring layer, and
a third wiring layer disposed on the second insulating layer and electrically connected to the second wiring layer.

9. The semiconductor package of claim 1, wherein
the apertured interconnection layer comprises:
a first insulating layer,
a first wiring layer disposed on a first surface of the first insulating layer,
a second wiring layer disposed on a second surface of the first insulating layer and electrically connected to the first wiring layer, wherein the first and second surfaces of the first insulating layer face away from each other,
a second insulating layer disposed on the first surface of the first insulating layer and covering the first wiring layer,
a third wiring layer disposed on the second insulating layer and electrically connected to the first wiring layer,
a third insulating layer disposed on the second surface of the first insulating layer and covering the second wiring layer, and
a fourth wiring layer disposed on the third insulating layer and electrically connected to the second wiring layer.

10. The semiconductor package of claim 1, wherein
an aspect ratio of the conductive post is 10 or less.

11. The semiconductor package of claim 1, wherein
the second semiconductor chip is in contact with the fourth interconnection layer.

12. The semiconductor package of claim 1, further comprising
a connection terminal disposed between the sub-package and the first interconnection layer.

13. The semiconductor package of claim 1, wherein
the conductive post is spaced apart from the first interconnection layer.

14. The semiconductor package of claim 1, wherein:
sidewalls of the first interconnection layer and the fourth interconnection layer terminate on the same plane, and
in a plan view, the sidewalls of the first interconnection layer and the fourth interconnection layer are spaced apart from the apertured interconnection layer by a horizontal distance.

15. A semiconductor package, comprising:
a first interconnection layer;
a sub-package disposed on the first interconnection layer and electrically connected to the first interconnection layer, the sub-package comprising:
a second interconnection layer,
an intermediate interconnection pattern disposed on the second interconnection layer and electrically connected to the second interconnection layer and having a through hole,
a first logic chip disposed within the through hole and electrically connected to the second interconnection layer,
a first encapsulant filling a portion of the through hole and covering a portion of the first logic chip, and
a third interconnection layer disposed on the first encapsulant and electrically connected to the intermediate interconnection pattern;
a second encapsulant covering a portion of the sub-package;
a second logic chip disposed on the second encapsulant and electrically connected to the third interconnection layer;
a third encapsulant covering a portion of the second logic chip;
a fourth interconnection layer disposed on the third encapsulant; and
a conductive post embedded in the third encapsulant and electrically connecting the third interconnection layer and the fourth interconnection layer.

16. The semiconductor package of claim 15, wherein
a wiring pitch of the second logic chip is narrower than a wiring pitch of the first logic chip.

17. The semiconductor package of claim 15, wherein
a thickness of the second logic chip is thicker than a thickness of the first logic chip.

18. The semiconductor package of claim 15, wherein
a width of the second logic chip is wider than a width of the first logic chip.

19. The semiconductor package of claim 15, wherein
an aspect ratio of the conductive post is 10 or less.

20. A package-on-package device, comprising:
a first semiconductor package; and
a second semiconductor package disposed on the first semiconductor package,
wherein the first semiconductor package comprises:
a first interconnection layer,
a sub-package disposed on the first interconnection layer,
a second encapsulant covering a portion of the sub-package,
a second semiconductor chip disposed on the second encapsulant,
a third encapsulant covering a portion of the second semiconductor chip,
a fourth interconnection layer disposed on the third encapsulant, and
a conductive post embedded in the third encapsulant and electrically connecting the sub-package and the fourth interconnection layer,
wherein the sub-package comprises:
a second interconnection layer,
an intermediate interconnection pattern disposed on the second interconnection layer and having a through hole,
a first semiconductor chip disposed within the through hole,
a first encapsulant filling a portion of the through hole and covering a portion of the first semiconductor chip, and
a third interconnection layer disposed on the first encapsulant.
